(19) United States
(12) Patent Application Publication
(10) Pub. No.: US 2023/0402471 A1
(43) Pub. Date: Dec. 14, 2023

(54) SOLID-STATE IMAGING APPARATUS, METHOD OF MANUFACTURING THE SAME, AND ELECTRONIC DEVICE

(71) Applicant: SONY SEMICONDUCTOR SOLUTIONS CORPORATION, Kanagawa (JP)

(72) Inventor: Kazuya SASAKI, Kanagawa (JP)

(73) Assignee: SONY SEMICONDUCTOR SOLUTIONS CORPORATION, Kanagawa (JP)

(21) Appl. No.: 18/248,916

(22) PCT Filed: Aug. 30, 2021
(86) PCT No.: PCT/JP2021/031767

§ 371 Date: Apr. 13, 2023

(30) Foreign Application Priority Data
Oct. 22, 2020 (JP) 2020-177600

(51) Int. Cl. H01L 27/146

(52) U.S. Cl. CPC H01L 27/14614; H01L 27/14645; H01L 27/14689

(57) ABSTRACT

To improve transfer of signal charges. A solid-state imaging apparatus includes: a first charge accumulation region and a second charge accumulation region provided separated from each other in a semiconductor layer; and a transfer transistor in which a channel is formed in a semiconductor layer adjacent to a gate electrode with a gate insulating film interposed between the semiconductor layer and the gate electrode, and signal charges accumulated in the first charge accumulation region are transferred to the second charge accumulation region through the channel. In addition, the gate insulating film has a thickness that is thinner on a downstream side in a signal charge transfer direction than on an upstream side in the signal charge transfer direction.

### TECHNICAL FIELD

The present technology (technology according to the present disclosure) relates to a solid-state imaging apparatus, a method of manufacturing the same, and an electronic device, and more particularly, to a solid-state imaging apparatus having a transfer transistor, a method of manufacturing the same, and a technology effective for application to the electronic device.

### BACKGROUND ART

Conventionally, in a solid-state imaging apparatus, signal charges accumulated in a photoelectric conversion unit are transferred to a floating diffusion by a transfer transistor.

### CITATION LIST

### Patent Document

Patent Document 1: Japanese Patent Application Laid-Open No. 2008-227263
Patent Document 2: Japanese Patent Application Laid-Open No. 2008-21925

### SUMMARY OF THE INVENTION

### Problems to be Solved by the Invention

In a general solid-state imaging apparatus, a transfer transistor has a channel formed in a semiconductor layer adjacent to a gate electrode with a gate insulating film interposed between the semiconductor layer and the gate electrode. Then, the transfer transistor transfers the signal charges accumulated in the photoelectric conversion unit to the floating diffusion region through the channel.

However, because the channel is an inversion layer formed in the semiconductor layer when the transfer transistor is turned on, although there is some change due to impurities, the potential distribution basically becomes uniform in a signal charge transfer direction, and the transfer electric field tends to become weak. Therefore, a transfer defect such as an afterimage may occur due to the shortage of the transfer electric field in the channel, and the improvement is needed in the transfer defect. However, in view of other characteristics, it is difficult to take measures against the transfer defect only by adjusting the impurity distribution in the photoelectric conversion unit and the bias of the transfer gate.

An object of the present technology is to provide a solid-state imaging apparatus that can improve transfer of the signal charges, a method of manufacturing the same, and an electronic device.

### Solution to Problems

(1) A solid-state imaging apparatus according to an aspect of the present technology includes: a first charge accumulation region and a second charge accumulation region provided separated from each other in a semiconductor layer; and a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel, in which the gate insulating film has a thickness that is thinner on a downstream side in a transfer direction of the signal charges than on an upstream side in the transfer direction of the signal charges.

(2) Furthermore, a solid-state imaging apparatus according to another aspect of the present technology includes: a first charge accumulation region and a second charge accumulation region provided separated from each other in a semiconductor layer; and a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel, in which the gate insulating film includes an eighth portion having a first relative dielectric constant and a ninth portion having a second relative dielectric constant higher than the first relative dielectric constant, and the ninth portion is provided on a downstream side in a transfer direction of the signal charges in the gate insulating film.

(3) Furthermore, a method of manufacturing a solid-state imaging apparatus according to an aspect of the present technology includes: forming a first charge accumulation region and a second charge accumulation region in a semiconductor layer; forming a transfer transistor having a gate electrode and a gate insulating film and configured to transfer signal charges accumulated in the first charge accumulation region to the second charge accumulation region; and forming the gate insulating film having a thickness that is thinner on a downstream side in a transfer direction of the signal charges than a thickness of the gate insulating film on an upstream side in the transfer direction of the signal charges.

(4) Furthermore, a method of manufacturing a solid-state imaging apparatus according to another aspect of the present technology includes: forming a first charge accumulation region and a second charge accumulation region in a semiconductor layer; forming a transfer transistor having a gate electrode and a gate insulating film and configured to transfer signal charges accumulated in the first charge accumulation region to the second charge accumulation region; and forming the gate insulating film having a larger relative dielectric constant on a downstream side in a transfer direction of the signal charges than a relative dielectric constant of the gate insulating film on an upstream side in the transfer direction of the signal charges.

(5) Furthermore, an electronic device according to an aspect of the present technology includes any one of the semiconductor devices of (1) and (2) described above.

### BRIEF DESCRIPTION OF DRAWINGS

FIG. 1 is a diagram showing an overall configuration of a solid-state imaging apparatus according to a first embodiment of the present technology.

FIG. 2 is an equivalent circuit diagram showing a configuration example of a pixel.

FIG. 3 is a diagram showing a cross-sectional configuration of a pixel region in a case where the pixel region is cut along a line A-A in FIG. 1.

FIG. 4A is a diagram showing a planar configuration of a transfer transistor of a solid-state imaging apparatus according to a comparative example.

FIG. 4B is a diagram showing a cross-sectional configuration of the transfer transistor in a case where the transfer transistor is cut along a line B-B in FIG. 4A.

FIG. 4C is a diagram showing a potential distribution on the surface of a semiconductor layer of the transfer transistor of the solid-state imaging apparatus according to the comparative example.

FIG. 5A is a diagram showing a planar configuration of a transfer transistor of a solid-state imaging apparatus according to the first embodiment of the present technology.

FIG. 5B is a diagram showing a cross-sectional configuration of the transfer transistor in a case where the transfer transistor is cut along a line C-C in FIG. 4A.

FIG. 5C is a diagram showing a potential distribution on the surface of a semiconductor layer of the transfer transistor of the solid-state imaging apparatus according to the first embodiment of the present technology.

FIG. 6A is a process cross-sectional view of a method of manufacturing the solid-state imaging apparatus according to the first embodiment of the present technology.

FIG. 6B is a process cross-sectional view following FIG. 6A.

FIG. 6C is a process cross-sectional view following FIG. 6B.

FIG. 6D is a process cross-sectional view following FIG. 6C.

FIG. 6E is a process cross-sectional view following FIG. 6D.

FIG. 7A is a process cross-sectional view of a method of manufacturing the solid-state imaging apparatus according to a modified example 1 of the first embodiment of the present technology.

FIG. 7B is a process cross-sectional view following FIG. 7A.

FIG. 7C is a process cross-sectional view following FIG. 7B.

FIG. 7D is a process cross-sectional view following FIG. 7C.

FIG. 7E is a process cross-sectional view following FIG. 7D.

FIG. 8 is a diagram showing a cross-sectional configuration of a transfer transistor of a solid-state imaging apparatus according to a modified example 2 of the first embodiment of the present technology.

FIG. 9 is a diagram showing a cross-sectional configuration of a transfer transistor of a solid-state imaging apparatus according to a modified example 3 of the first embodiment of the present technology.

FIG. 10 is a diagram showing a cross-sectional configuration of a transfer transistor of a solid-state imaging apparatus according to a modified example 4 of the first embodiment of the present technology.

FIG. 11A is a diagram showing a planar configuration of a transfer transistor of a solid-state imaging apparatus according to a second embodiment of the present technology.

FIG. 11B is a diagram showing a cross-sectional configuration of the transfer transistor in a case where the transfer transistor is cut along a line D-D in FIG. 11A.

FIG. 12A is a diagram showing a planar configuration of a transfer transistor of a solid-state imaging apparatus according to a modified example of the second embodiment of the present technology.

FIG. 12B is a diagram showing a cross-sectional configuration of the transfer transistor in a case where the transfer transistor is cut along a line E-E in FIG. 12A.

FIG. 13 is a diagram showing a cross-sectional configuration of a transfer transistor of a solid-state imaging apparatus according to a third embodiment of the present technology.

FIG. 14A is a process cross-sectional view of a method of manufacturing the solid-state imaging apparatus according to the third embodiment of the present technology.

FIG. 14B is a process cross-sectional view following FIG. 14A.

FIG. 14C is a process cross-sectional view following FIG. 14B.

FIG. 14D is a process cross-sectional view following FIG. 14C.

FIG. 14E is a process cross-sectional view following FIG. 14D.

FIG. 15 is a diagram showing a cross-sectional configuration of a transfer transistor of a solid-state imaging apparatus according to a modified example of the third embodiment of the present technology.

FIG. 16A is a process cross-sectional view of a method of manufacturing the solid-state imaging apparatus according to the third embodiment of the present technology.

FIG. 16B is a process cross-sectional view following FIG. 16A.

FIG. 16C is a process cross-sectional view following FIG. 16B.

FIG. 16D is a process cross-sectional view following FIG. 16C.

FIG. 16E is a process cross-sectional view following FIG. 16D.

FIG. 16F is a process cross-sectional view following FIG. 16E.

FIG. 17A is a diagram showing a planar configuration of a transfer transistor of a solid-state imaging apparatus according to a fourth embodiment of the present technology.

FIG. 17B is a schematic diagram schematically representing a cross-sectional configuration of the transfer transistor in FIG. 17A.

FIG. 18 is a diagram showing a cross-sectional configuration of a transfer transistor of a solid-state imaging apparatus according to a fifth embodiment of the present technology.

FIG. 19 is a schematic configuration diagram of an electronic device according to a sixth embodiment of the present technology.

### MODE FOR CARRYING OUT THE INVENTION

Hereinafter, embodiments of the present technology are described in detail with reference to the drawings.

Note that, in all the drawings for describing the embodiments of the present technology, components having the same functions are denoted by the same reference numerals, and repeated description thereof are omitted.

In addition, each drawing is schematic and there is a case where the drawing is different from an actual one. In addition, the following embodiments exemplify an apparatus and a method for embodying the technical idea of the present technology, and do not specify the configuration as follows. That is, various modifications can be made to the technical idea of the present technology within the technical scope described in the claims.

Furthermore, in the following embodiments, for convenience, description is made on the assumption that a signal charge (carrier) photoelectrically converted by the photoelectric conversion unit is an electron (e−), but it is a matter of course that the present technology can be applied to a case where the signal charge photoelectrically converted by the photoelectric conversion unit is a hole.

### First Embodiment

In a first embodiment, an example in which the present technology is applied to a solid-state imaging apparatus that is a back-illuminated complementary metal oxide semiconductor (CMOS) image sensor is described.

<Configuration of Solid-State Imaging Apparatus>

First, an overall configuration of a solid-state imaging apparatus 1 is described.

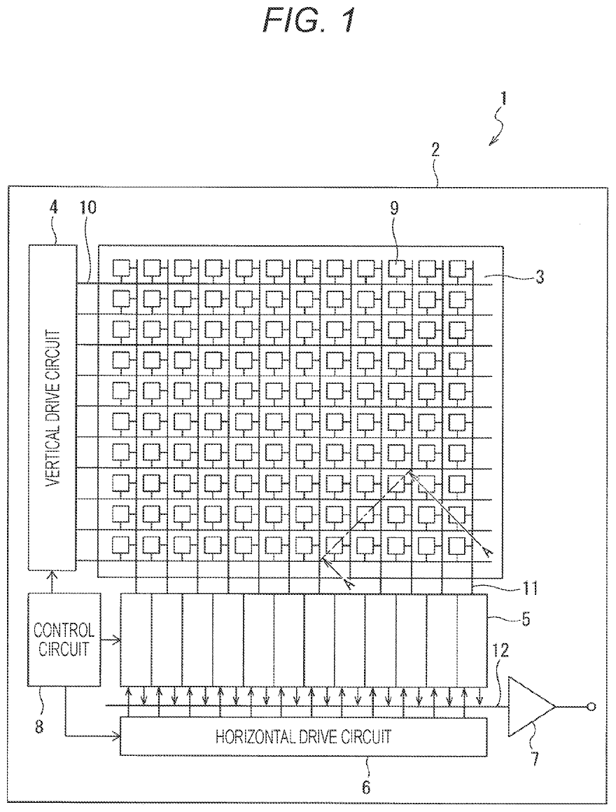

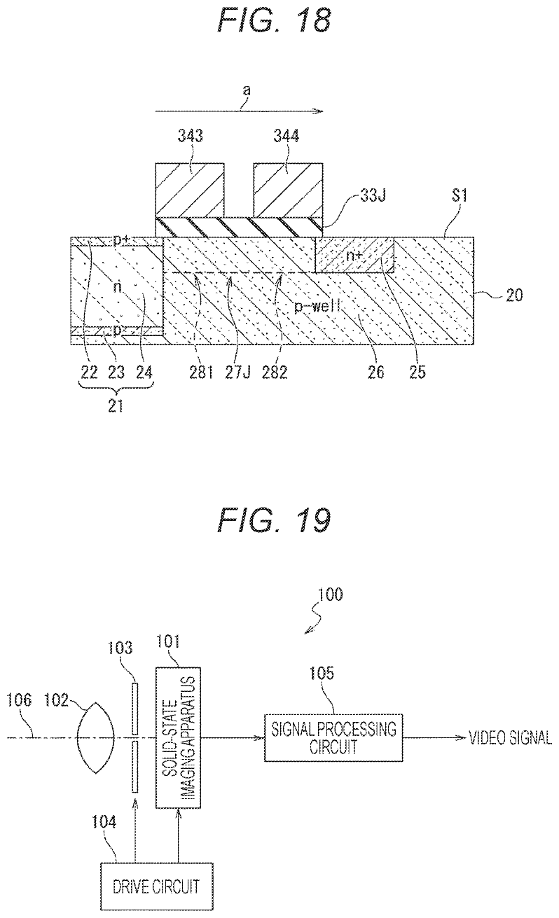

As shown in FIG. 1, a solid-state imaging apparatus 1 according to the first embodiment of the present technology mainly includes a semiconductor chip 2 whose two-dimensional planar shape is a rectangular shape in plan view. That is, the solid-state imaging apparatus 1 is mounted on the semiconductor chip 2. As shown in FIG. 19, the solid-state imaging apparatus 1 takes in image light (incident light 106) from a subject via an optical lens 102, converts an amount of the incident light 106 formed on the imaging surface into an electrical signal on a pixel-by-pixel basis, and outputs the electrical signal as a pixel signal.

As shown in FIG. 1, the semiconductor chip 2 includes a pixel region 3, a vertical drive circuit 4, column signal processing circuits 5, a horizontal drive circuit 6, an output circuit 7, a control circuit 8, a pixel 9, a pixel drive wiring line 10, a vertical signal line 11, and a horizontal signal line 12.

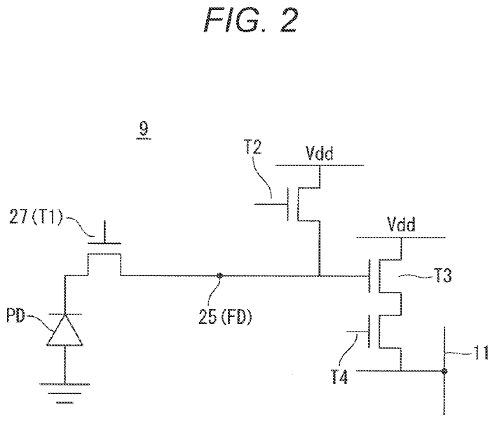

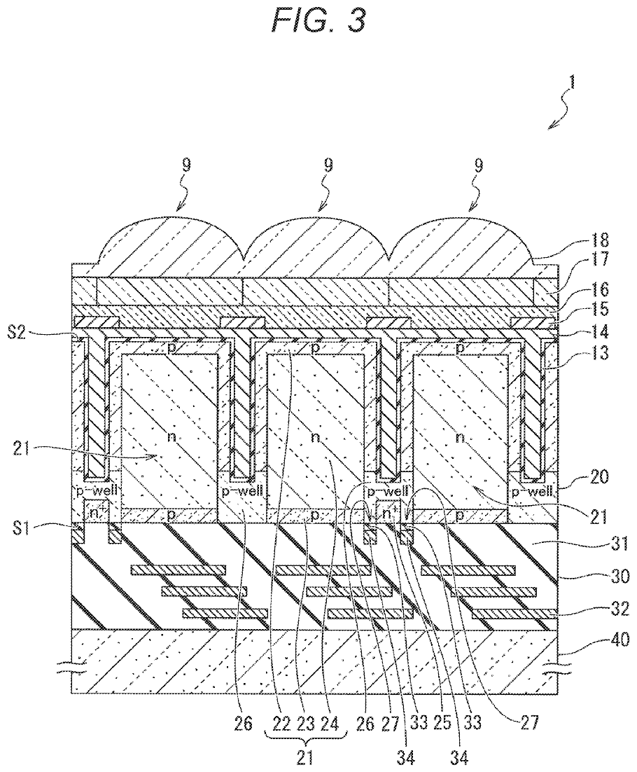

The pixel region 3 includes a plurality of the pixels 9 regularly aligned in a two-dimensional array. The pixel 9 includes a photoelectric conversion unit 21 shown in FIG. 3 and a plurality of pixel transistors (not illustrated). As the plurality of pixel transistors, for example, as shown in FIG. 2, four transistors which are a transfer transistor 27 (T1), a reset transistor T2, a selection transistor T4, and an amplification transistor T3 can be adopted. Alternatively, for example, three transistors excluding the selection transistor T4 may be adopted. The photoelectric conversion unit 21 shown in FIG. 3 includes a photodiode PD shown in FIG. 2.

In FIG. 1, the vertical drive circuit 4 includes, for example, a shift register, selects a desired one of the pixel drive wiring lines 10, supplies a pulse for driving the pixel 9 to the selected pixel drive wiring line 10, and drives each pixel 9 row by row. That is, the vertical drive circuit 4 selectively scans each pixel 9 in the pixel region 3 sequentially in the vertical direction row by row, and supplies a pixel signal to the column signal processing circuit 5 through the vertical signal line 11, the pixel signal being based on signal charges generated according to the amount of received light in the photoelectric conversion unit 21 in each pixel 9.

The column signal processing circuit 5 is disposed, for example, for each column of the pixels 9, and performs signal processing such as noise removal for each pixel column on signals output from the pixels 9 for one row. For example, the column signal processing circuit 5 performs signal processing such as correlated double sampling (CDS) for removing pixel-specific fixed pattern noise and analog digital (AD) conversion.

The horizontal drive circuit 6 includes, for example, a shift register, sequentially outputs horizontal scanning pulses to the column signal processing circuits 5, sequentially selects each of the column signal processing circuits 5, and causes each of the column signal processing circuits 5 to output a pixel signal subjected to signal processing to the horizontal signal line 12.

The output circuit 7 performs signal processing on the pixel signals sequentially supplied from each of the column signal processing circuits 5 through the horizontal signal line 12, and outputs the pixel signals. As the signal processing, for example, buffering, black level adjustment, column variation correction, various types of digital signal processing, and the like can be used.

The control circuit 8 generates a clock signal or a control signal serving as a reference of operations of the vertical drive circuit 4, the column signal processing circuit 5, the horizontal drive circuit 6, and the like on the basis of a vertical synchronization signal, a horizontal synchronization signal, and a master clock signal. Then, the control circuit 8 outputs the generated clock signal and control signal to the vertical drive circuit 4, the column signal processing circuit 5, the horizontal drive circuit 6, and the like.

FIG. 2 is an equivalent circuit of a pixel of the solid-state imaging apparatus 1 according to the first embodiment of the present technology. As shown in FIG. 2, an anode of a photodiode PD that is a photoelectric conversion unit of the pixel 9 is grounded, and a source of the transfer transistor 27 being an active element is connected to a cathode of the photodiode PD. A floating diffusion region 25 (FD) in a floating state is connected to a drain of the transfer transistor 27. The floating diffusion region 25 is connected to a source of the reset transistor T2 being an active element and a gate of the amplification transistor T3 being an active element. A source of the amplification transistor T3 is connected to a drain of the selection transistor T4 being an active element, and a drain of the amplification transistor T3 is connected to a power supply Vdd. A source of the selection transistor T4 is connected to the vertical signal line 11. A drain of the reset transistor T2 is connected to the power supply Vdd.

During the operation of the solid-state imaging apparatus 1 according to the first embodiment, signal charges generated in the photodiode PD of the pixel 9 are accumulated in the floating diffusion region 25 of the pixel 9 via the transfer transistor 27 of the pixel 9. Then, the signal charges accumulated in the floating diffusion region 25 of the pixel 9 are each read and applied to a gate electrode of the amplification transistor T3 of the pixel 9. A horizontal line selection control signal is supplied from a vertical shift register to a gate electrode of the selection transistor T4 of the pixel 9. By setting the selection control signal to a high (H) level, the selection transistor T4 is conducted, and a current corresponding to a potential of the floating diffusion region 25 of the pixel 9 amplified by the amplification transistor T3 of the pixel 9 flows through the vertical signal line 11. Furthermore, by setting the reset control signal applied to the gate electrode of the reset transistor T2 to the high (H) level, the reset transistor T2 of the pixel 9 is conducted, and the signal charges accumulated in the floating diffusion region 25 of the pixel 9 are reset.

<Detailed Structure of Solid-State Imaging Apparatus>

Next, a detailed structure of the solid-state imaging apparatus 1 according to the first embodiment is described. FIG. 3 is a diagram illustrating a cross-sectional configuration of the pixel region 3 of the solid-state imaging apparatus 1 according to the first embodiment.

As shown in FIG. 3, the solid-state imaging apparatus 1 of the first embodiment includes a semiconductor layer 20, and among a first surface S1 and a second surface S2 located on opposite sides of the semiconductor layer 20, a fixed charge film 13, an insulating film 14, a light shielding film 15, a planarization film 16, a color filter layer 17, and a microlens (on-chip lens) 18 sequentially laminated on the second surface S2 side. Moreover, a multilayer wiring layer 30 and a support substrate 40 are laminated in this order on the first surface S1 side of the semiconductor layer 20.

Here, the first surface S1 of the semiconductor layer 20 may be referred to as an element formation surface or a main surface, and the second surface S2 may be referred to as a light incident surface or a back surface.

The semiconductor layer 20 includes, for example, a semiconductor substrate including silicon (Si), and forms the pixel region 3 as shown in FIG. 1. In the pixel region 3, as shown in FIG. 3, a plurality of the photoelectric conversion units 21 formed in the semiconductor layer 20, that is, the plurality of pixels 9 including the plurality of photoelectric conversion units 21 embedded in the semiconductor layer 20 is arranged in a two-dimensional matrix.

As shown in FIG. 3, the photoelectric conversion unit 21 includes semiconductor regions 22 and 23 of a first conductivity type (for example, a p-type) formed on the second surface S2 side and the first surface S1 side of the semiconductor layer 20, respectively, and a semiconductor region 24 of a second conductivity type (for example, an n-type) formed between the semiconductor regions 22 and 23 of the first conductivity type. In the photoelectric conversion unit 21, the above-described photodiode PD is configured by forming a pn junction between the semiconductor regions 22 and 23 of the first conductivity type and the semiconductor region 24 of the second conductivity type. The photoelectric conversion unit 21 generates signal charges corresponding to the amount of incident light, accumulates the generated signal charges in the semiconductor region 24 of the second conductivity type, and temporarily holds the signal charges. In addition, electrons that cause dark current generated at an interface of the semiconductor layer 20 are absorbed by holes that are majority carriers of the semiconductor regions 22 and 23 of the first conductivity type formed on the first surface S1 and the second surface S2 of the semiconductor layer 20, which causes the dark current to be suppressed. The photoelectric conversion unit 21 is a first charge accumulation region that functions as a source region of the transfer transistor 27 described later.

The floating diffusion region 25 (FD) is formed in the semiconductor layer 20, that is, embedded in the semiconductor layer 20. The floating diffusion region 25 is a semiconductor region of the second conductivity type (for example, an n-type), and is a second charge accumulation region that functions as a drain region of the transfer transistor 27 described later. The floating diffusion region 25 temporarily stores (accumulates) the signal charges transferred from the photoelectric conversion unit 21 via the transfer transistor 27.

The photoelectric conversion unit 21 being the first charge accumulation region and the floating diffusion region 25 being the second charge accumulation region are provided on the first surface S1 side of the semiconductor layer 20 in a separated manner from each other in plan view.

The transfer transistor 27 is, for example, an n-channel conductivity type metal oxide semiconductor field effect transistor (MOSFET) provided in a well region 26 of the semiconductor layer 20. Here, the well region 26 is the first conductivity type (for example, a p-type). In addition, the transfer transistor 27 is provided so as to form a channel between the photoelectric conversion unit 21 and the floating diffusion region 25, and includes a gate insulating film 33 and a gate electrode 34 sequentially laminated on the second surface S2 of the semiconductor layer 20.

The transfer transistor 27 transfers the signal charges from the photoelectric conversion unit 21 functioning as a source region to the floating diffusion region 25 functioning as a drain region. When a gate-source voltage of the transfer transistor 27 is set to the high (H) level, a part of the well region 26 of the first conductivity type is inverted to the second conductivity type along the gate length direction of the gate electrode 34 to become a channel. Then, the photoelectric conversion unit 21 and the floating diffusion region 25 are electrically connected to each other by the channel. Therefore, the signal charges flow from the photoelectric conversion unit 21 to the floating diffusion region 25. Furthermore, when the gate-source voltage of the transfer transistor 27 is set to the low (L) level, the photoelectric conversion unit 21 and the floating diffusion region 25 are electrically separated from each other, that is, the potential is separated, and the signal charges are not transferred.

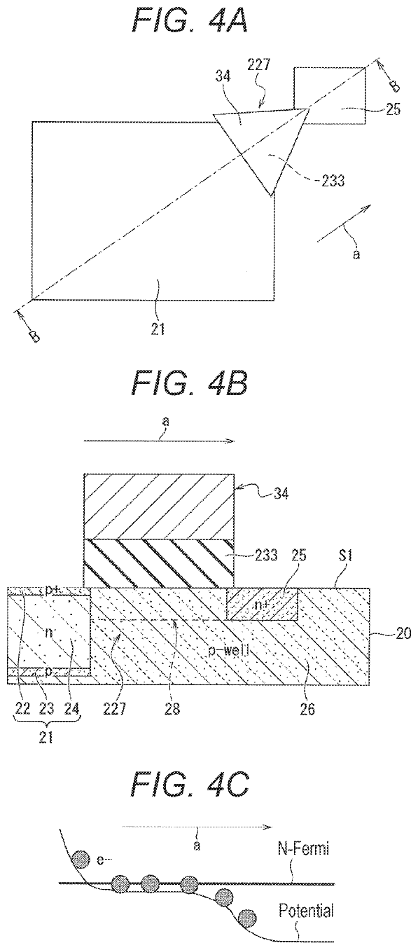

Furthermore, the signal charge transfer direction is a direction from the photoelectric conversion unit 21 (first charge accumulation region) functioning as a source region toward the floating diffusion region 25 (second charge accumulation region) functioning as a drain region, that is, a direction indicated by an arrow a (see FIG. 4A).

The gate electrode 34 includes, for example, a doped polysilicon (Poly-Si) film. Furthermore, the gate insulating film 33 includes, for example, a silicon oxide (SiO₂) film.

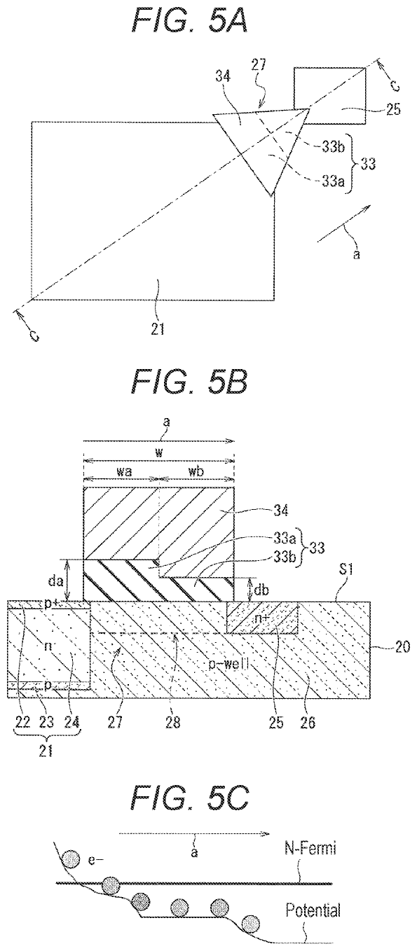

Referring to FIG. 5B, in the transfer transistor 27 of the first embodiment, a channel 28 (inversion layer) is formed in the semiconductor layer 20 (well region 26) adjacent to the gate electrode 34 with the gate insulating film 33 interposed between the semiconductor layer 20 and the gate electrode 34, and the signal charges (e−) are transferred from the photoelectric conversion unit (first charge accumulation region) 21 to the floating diffusion region (second charge accumulation region) 25 through this channel 28. In addition, the transfer transistor 27 of the first embodiment is configured as a lateral type in which a current flows (signal charges move) along the first surface S1 in a surface layer part on the first surface S1 side of the semiconductor layer 20. In addition, the transfer transistor 27 of the first embodiment is configured as an enhancement type (normally-off type) in which the channel 28 is formed only when a gate voltage is applied.

Here, the semiconductor layer 20 adjacent to the gate electrode 34 with the gate insulating film 33 interposed between the semiconductor layer 20 and the gate electrode 34 can be defined as the semiconductor layer 20 facing or opposed to the gate electrode 34 with the gate insulating film 33 interposed between the semiconductor layer 20 and the gate electrode 34.

As shown in FIG. 3, the multilayer wiring layer 30 is formed on the first surface S1 side of the semiconductor layer 20 so as to cover the gate insulating film 33 and the gate electrode 34, and includes an interlayer insulating film 31 and a plurality of wiring layers 32 laminated in a plurality of stages with the interlayer insulating film 31 interposed between the wiring layers 32. Then, a pixel transistor constituting each pixel 9 is driven via a wiring line formed in each wiring layer 32.

The support substrate 40 is formed on a surface of the multilayer wiring layer 30 on a side opposite to the side facing the semiconductor layer 20. The support substrate 40 is a substrate for securing the strength of the semiconductor layer 20 at the manufacturing stage of the solid-state imaging apparatus 1. As material of the support substrate 40, for example, silicon (Si) can be used.

In the solid-state imaging apparatus 1 having the above configuration, light is emitted from the back surface side (second surface S2 side) of the semiconductor layer 20, the emitted light passes through the microlens 18 and the color filter layer 17, and the transmitted light is photoelectrically converted by the photoelectric conversion unit 21, which causes the signal charges to be generated. Then, the generated signal charges are output as a pixel signal by the vertical signal line 11 shown in FIG. 1 formed in the wiring layer 32 via the pixel transistor formed on the second surface S2 side of the semiconductor layer 20.

<Configuration of Transfer Transistor>

Next, the transfer transistor 27 of the solid-state imaging apparatus 1 according to the first embodiment is described with reference to FIGS. 5A to 5C. However, before the description, first, the configuration of a transfer transistor 227 of a solid-state imaging apparatus according to a comparative example is described with reference to FIGS. 4A to 4C.

Note that, in FIG. 5B, in order to make the drawing easy to see, a state in which the gate electrode 34 and the gate insulating film 33 overlap with the photoelectric conversion unit 21 and the floating diffusion region 25 is not necessarily matched with a state in FIG. 5A. Similarly, in FIG. 4B, in order to make the drawing easy to see, a state in which the gate electrode 34 and a gate insulating film 233 overlap with the photoelectric conversion unit 21 and the floating diffusion region 25 is not necessarily matched with a state in FIG. 4A. In addition, in FIGS. 5B and 4B, the photoelectric conversion unit 21 shown in FIG. 3 is simplified.

Furthermore, in FIGS. 5C and 4C, the signal charges transferred by the transfer transistor are described as electrons, but a similar effect can be obtained in holes.

<Configuration of Transfer Transistor in Comparative Example>

As shown in the plan view of FIG. 4A, the gate electrode 34 and the gate insulating film 233 of the transfer transistor 227 according to the comparative example have a triangular shape in plan view. As shown in FIG. 4A, in the gate electrode 34 and the gate insulating film 233 of the transfer transistor 227, one vertex side of the triangle overlaps the floating diffusion region 25 in plan view, and the remaining two vertex sides of the triangle overlap the photoelectric conversion unit 21 in plan view.

In addition, as shown in FIG. 4B, the transfer transistor 227 includes the gate insulating film 233 provided on the first surface S1 of the semiconductor layer 20 and having a uniform thickness, and the gate electrode 34 provided on the gate insulating film 233. When the gate-source voltage of the transfer transistor 227 is set to the high (H) level, the photoelectric conversion unit 21 and the floating diffusion region 25 are electrically connected to each other by the channel 28, and the signal charges flow from the photoelectric conversion unit 21 to the floating diffusion region 25 via the channel 28. An arrow a shown in FIGS. 4A, 4B, and 4C indicates the signal charge transfer direction.

Here, changing the potential of the semiconductor layer 20 by setting the gate-source voltage of the transfer transistor 227 to the high (H) level is referred to as modulation. In the transfer transistor 227 of the comparative example, the potential distribution on the first surface S1 of the semiconductor layer 20 is flat in the transfer direction (arrow a) of signal charges (e−) as shown in FIG. 4C.

When the potential distribution is flat in the signal charge transfer direction, the probability that the signal charges cannot be completely transferred and stop (the signal charges do not move) increases. Moreover, the signal charges (e−) that have stopped under the gate electrode 34 return to the photoelectric conversion unit 21 when the gate-source voltage of the transfer transistor 227 is set to the low (L) level. A phenomenon in which the signal charges (e−) return to the photoelectric conversion unit 21 in this manner is referred to as rising.

<Configuration of Transfer Transistor in the Present Technology>

On the other hand, as shown in FIGS. 5A and 5B, the gate insulating film 33 provided in the transfer transistor 27 according to the first embodiment of the present technology is different from the above-described transfer transistor 227 in that the thickness is different between the photoelectric conversion unit 21 side (the upstream side in the signal charge transfer direction) and the floating diffusion region 25 side (the downstream side in the signal charge transfer direction), in the transfer direction (the arrow a) of signal charges (e−). That is, the transfer transistor 27 of the first embodiment has a structure in which the film thickness of the gate insulating film 33 has locality.

As shown in FIG. 5B, the gate insulating film 33 has two portions, which are a first portion 33a having a first thickness da and a second portion 33b having a second thickness db thinner than the first thickness da. That is, the gate insulating film 33 has a step structure having different thicknesses. Here, the thickness is a thickness in a direction in which the gate insulating film 33 is laminated, that is, a film thickness. The first portion 33a having the first thickness da is provided on the photoelectric conversion unit 21 side, that is, on the upstream side in the signal charge (e−) transfer direction, and the second portion 33b having the second thickness db is provided on the floating diffusion region 25 side, that is, on the downstream side in the signal charge (e−) transfer direction. That is, the gate insulating film 33 has a thickness that is thinner on the downstream side in the signal charge (e−) transfer direction than on the upstream side in the signal charge transfer direction. In addition, the first portion 33a and the second portion 33b include the same material. In addition, a width wa of the first portion 33a in the signal charge (e−) transfer direction is equal to a width wb of the second portion 33b in the signal charge (e−) transfer direction in design.

Furthermore, the gate electrode 34 and the gate insulating film 33 are provided on the semiconductor layer 20 having a planar shape. As shown in FIG. 5B, the entire gate electrode 34 and the entire gate insulating film 33 face the flat first surface S1 of the semiconductor layer 20. When the gate electrode 34 is turned on (a gate voltage is applied to the gate electrode 34), the channel 28 is formed in the semiconductor layer 20 to which the gate electrode 34 and the gate insulating film 33 face. That is, the channel 28 is formed at a portion between the one end side and the other end side in the gate length direction of the gate electrode 34 and the gate insulating film 33, over the one end side and the other end side. The gate insulating film 33 has the first thickness da and the second thickness db in the portion corresponding to the channel 28.

As described above, by forming the downstream side of the gate insulating film 33 (the second portion 33b) in the signal charge (e−) transfer direction is made thinner than the upstream side (the first portion 33a), in the semiconductor layer 20 adjacent to the gate electrode 34 with the gate insulating film 33 interposed between the semiconductor layer 20 and the gate electrode 34, the portion corresponding to the second portion 33b of the gate insulating film 33 is modulated more strongly than the portion corresponding to the first portion 33a. Therefore, the potential distribution on the first surface S1 of the semiconductor layer 20 is drawn as shown in FIG. 5C. That is, as shown in FIG. 5C, the potential on the downstream side in the signal charge (e−) transfer direction is lower than the potential on the upstream side, and is not flat. Then, a potential gradient is formed in the signal charge (e−) transfer direction. As a result, the signal charge (e−) transfer speed is increased.

In the solid-state imaging apparatus 1 according to the first embodiment, because the gate insulating film 33 has the step structure having different thicknesses, the signal charge (e−) transfer speed can be improved without changing other characteristics such as drive conditions and impurity distribution.

Furthermore, in the solid-state imaging apparatus 1 according to the first embodiment, because the film thickness of the gate insulating film 33 on the downstream side in the signal charge transfer direction is configured to be thinner than that on the upstream side, the potential of the modulated portion of the semiconductor layer 20 is lower on the downstream side in the signal charge transfer direction than that on the upstream side. Therefore, a gradient of the potential can be provided in the signal charge transfer direction. Therefore, the transfer speed can be increased. In addition, because the transfer speed can be increased, the signal charges can be prevented from stopping and the rising phenomenon can be prevented from occurring.

Note that the gate electrode 34 may or may not overlap the photoelectric conversion unit 21 and the floating diffusion region 25.

<Method of Manufacturing Solid-State Imaging Apparatus>

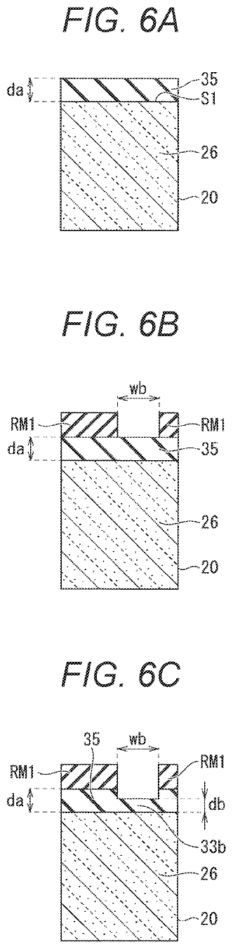

Next, a method of manufacturing the solid-state imaging apparatus 1 according to the first embodiment of the present technology is described with reference to FIGS. 6A to 6E. Note that, here, in the methods of manufacturing the solid-state imaging apparatus 1, only the method of manufacturing the transfer transistor 27 is described. For the manufacturing methods apart from the above, it is sufficient that known manufacturing methods are used.

<Method of Manufacturing Transfer Transistor>

In FIGS. 6A to 6E, it is assumed that the photoelectric conversion unit 21 and the floating diffusion region 25 are already formed in the semiconductor layer 20, and a detailed illustration of the inside of the semiconductor layer 20 is omitted. Furthermore, the cross sections shown in FIGS. 6A to 6E are the same as the cross section shown in FIG. 5B.

First, as shown in FIG. 6A, an insulating material 35 having a thickness of the first thickness da is formed on the first surface S1 of the semiconductor layer 20. The insulating material 35 is a material constituting the gate insulating film 33. The insulating material 35 having the first thickness da is formed by a deposition method such as the chemical vapor deposition (CVD) method, for example.

Next, as shown in FIG. 6B, a mask RM1 is formed on the insulating material 35 by a known photolithography technique. The mask RM1 is a resist mask, and has an opening whose width in the signal charge transfer direction is the same as the width wb of the second portion 33b.

Next, as shown in FIG. 6C, the mask RM1 is used as an etching mask, and the insulating material 35 exposed from the opening of the mask RM1 is etched until the thickness of the insulating material 35 becomes equal to the second thickness db that is the thickness of the second portion 33b. As a result, the second portion 33b is formed. In this manner, the thickness of the second portion 33b on the downstream side in the signal charge transfer direction is formed to be thinner than the thickness of the first portion 33a on the upstream side in the signal charge transfer direction.

Next, after the mask RM1 is removed, as shown in FIG. 6D, a gate material 36 is formed on the insulating material 35, and subsequently, a mask RM2 is formed on the gate material 36 by a known photolithography technique. The gate material 36 is a material constituting the gate electrode 34. The mask RM2 has a width w obtained by adding the width wa of the first portion 33a and the width wb of the second portion 33b in the signal charge transfer direction. Then, using the mask RM2 as an etching mask, the gate material 36 and the insulating material 35 are sequentially patterned to form the gate electrode 34 and the gate insulating film 33 as shown in FIG. 6E. Through this process, the gate insulating film 33 having the first portion 33a and the second portion 33b having different film thicknesses is formed.

<Effects>

In the solid-state imaging apparatus 1 according to the first embodiment, because the gate insulating film 33 has the step structure having different thicknesses, the signal charge transfer speed can be improved without changing other characteristics such as drive conditions and impurity distribution.

Furthermore, in the solid-state imaging apparatus 1 according to the first embodiment, because the film thickness of the gate insulating film 33 on the downstream side in the signal charge transfer direction is formed to be thinner than that on the upstream side, the potential of the modulated portion of the semiconductor layer 20 is lower on the downstream side in the signal charge transfer direction than that on the upstream side. Therefore, a gradient of the potential can be provided in the signal charge transfer direction. Therefore, the transfer speed can be increased. In addition, because the transfer speed can be increased, the signal charges can be prevented from stopping and the rising phenomenon can be prevented from occurring.

### Modified Example 1 of First Embodiment

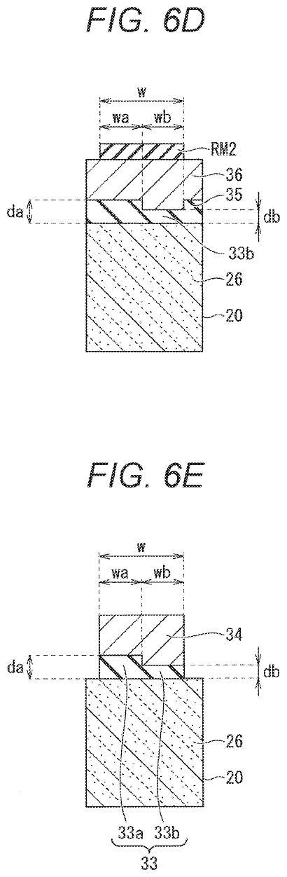

Next, a modified example 1 of the first embodiment of the present technology is described with reference to FIGS. 7A to 7E. In the modified example 1 of the first embodiment of the present technology, another method of manufacturing the transfer transistor 27 of the solid-state imaging apparatus 1 described in the first embodiment is described.

<Method of Manufacturing Transfer Transistor>

In FIGS. 7A to 7E, it is assumed that the photoelectric conversion unit 21 and the floating diffusion region 25 are already formed in the semiconductor layer 20, and a detailed illustration of the inside of the semiconductor layer 20 is omitted. Furthermore, the cross sections shown in FIGS. 7A to 7E are the same as the cross section shown in FIG. 5B.

First, as shown in FIG. 7A, the insulating material 35 having a thickness of the second thickness db is formed on the first surface S1 of the semiconductor layer 20. The insulating material 35 is a material constituting the gate insulating film 33. The insulating material 35 having the second thickness db is formed by a deposition method such as the CVD method, for example.

Next, as shown in FIG. 7B, a mask RM3 is formed on the insulating material 35 by a known photolithography technique. The mask RM is a resist mask, and has an opening whose width in the signal charge transfer direction is the same as the width wa of the first portion 33a.

Next, as shown in FIG. 7C, the insulating material 35 is deposited. The insulating material 35 is deposited until the thickness of the insulating material 35 at the opening of the mask RM3 becomes equal to the first thickness da which is the thickness of the first portion 33a. Then, by selectively removing the mask RM3 and the insulating material 35 on the mask RM3 using the lift-off method, the first portion 33a is formed. In this manner, the thickness of the first portion 33a is formed thick such that the thickness of the second portion 33b on the downstream side in the signal charge transfer direction is formed to be thinner than the thickness of the first portion 33a on the upstream side in the signal charge transfer direction.

Next, as shown in FIG. 7D, the gate material 36 is formed on the insulating material 35, and subsequently, a mask RM4 is formed on the gate material 36 by a known photolithography technique. The gate material 36 is a material constituting the gate electrode 34. The mask RM4 has a width obtained by adding the width wa of the first portion 33a and the width wb of the second portion 33b in the signal charge transfer direction. Then, using the mask RM4 as an etching mask, the gate material 36 and the insulating material 35 are sequentially patterned to form the gate electrode 34 and the gate insulating film 33 as shown in FIG. 7E. Through this process, the gate insulating film 33 having the first portion 33a and the second portion 33b having different film thicknesses is formed.

<Effects>

According to the method of manufacturing the solid-state imaging apparatus 1 according to the modified example 1 of the first embodiment, effects similar to those of the method of manufacturing the solid-state imaging apparatus 1 according to the first embodiment described above can be obtained.

Note that, if necessary, the masks RM3 and RM4 may be hard masks instead of resist masks.

### Modified Example 2 of First Embodiment

<Configuration of Solid-State Imaging Apparatus>

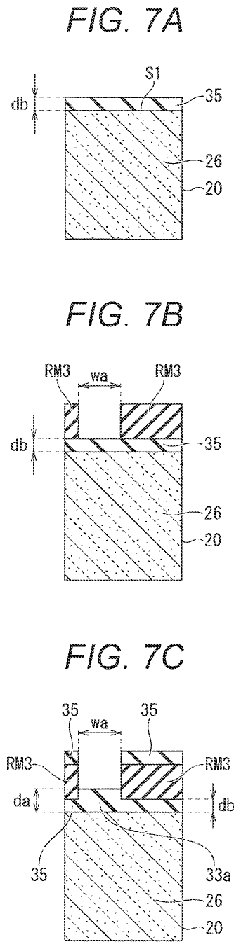

Next, a modified example 2 of the first embodiment of the present technology is described with reference to FIG. 8. The modified example 2 of the first embodiment is different from the above-described first embodiment in that the solid-state imaging apparatus 1 includes a transfer transistor 27A instead of the transfer transistor 27, and the configuration of the solid-state imaging apparatus 1 other than this is basically similar to the configuration of the solid-state imaging apparatus 1 of the above-described first embodiment. Hereinafter, the transfer transistor 27A is described.

<Configuration of Transfer Transistor>

As shown in FIG. 8, the transfer transistor 27A includes a gate insulating film 33A. The gate insulating film 33A has a first portion 33Aa and a second portion 33Ab. A width wAa of the first portion 33Aa in the signal charge transfer direction is different from a width wAb of the second portion 33Ab in the signal charge transfer direction. FIG. 8 shows an example in which the width wAa of the first portion 33Aa in the signal charge transfer direction is smaller than the width wAb of the second portion 33Ab in the signal charge transfer direction.

<Effects>

According to the method of manufacturing the solid-state imaging apparatus 1 according to the modified example 2 of the first embodiment, effects similar to those of the solid-state imaging apparatus 1 according to the first embodiment described above can be obtained.

Note that the width wAa of the first portion 33Aa in the signal charge transfer direction may be larger than the width wAb of the second portion 33Ab in the signal charge transfer direction.

<Method of Manufacturing Transfer Transistor>

Next, a method of manufacturing the transfer transistor 27A of the solid-state imaging apparatus 1 according to the modified example 2 of the first embodiment of the present technology is described. The method of manufacturing the transfer transistor 27A is realized by changing the width wa to wAa and changing the width wb to wAb in the method of manufacturing the transfer transistor 27 according to the first embodiment described above.

<Effects>

According to the method of manufacturing the solid-state imaging apparatus 1 according to the modified example 2 of the first embodiment, effects similar to those of the method of manufacturing the solid-state imaging apparatus 1 according to the first embodiment described above can be obtained.

Note that the method of manufacturing the solid-state imaging apparatus 1 according to the modified example 2 of the first embodiment may be realized by changing the width wa to wAa and changing the width wb to wAb in the another method of manufacturing the solid-state imaging apparatus 1 according to the modified example 1 of the first embodiment described above.

### Modified Example 3 of First Embodiment

<Configuration of Solid-State Imaging Apparatus>

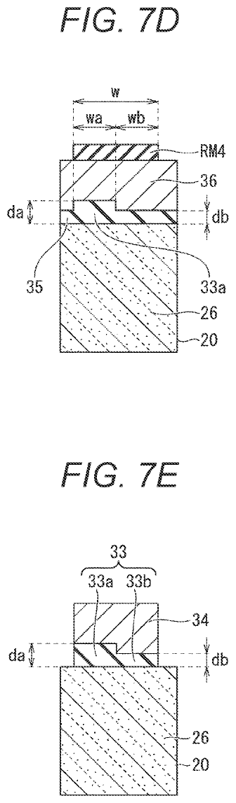

Next, a modified example 3 of the first embodiment of the present technology is described with reference to FIG. 9. The modified example 3 of the first embodiment is different from the above-described first embodiment in that the solid-state imaging apparatus 1 includes a transfer transistor 27B instead of the transfer transistor 27, and the configuration of the solid-state imaging apparatus 1 other than this is basically similar to the configuration of the solid-state imaging apparatus 1 of the above-described first embodiment. Hereinafter, the transfer transistor 27B is described.

<Configuration of Transfer Transistor>

As shown in FIG. 9, the transfer transistor 27B includes a gate insulating film 33B. The gate insulating film 33B includes a first portion 33a provided on the upstream side in the signal charge transfer direction and having the first thickness da, a second portion 33b provided on the downstream side in the signal charge transfer direction and having the second thickness db thinner than the first thickness da, and a third portion 33c provided between the first portion 33a and the second portion 33b. The thickness (third thickness) of the third portion 33c is thinner than the first thickness da of the first portion 33a and thicker than the second thickness db of the second portion 33b.

As shown in FIG. 9, the third portion 33c further includes two portions: a third portion 33c1 and a third portion 33c2. The third portion 33c1 and the third portion 33c2 are disposed in the order of the third portion 33c1 and the third portion 33c2 from the upstream side in the signal charge transfer direction. That is, the first portion 33a, the third portion 33c1, the third portion 33c2, and the second portion 33b are disposed in this order from the upstream side in the signal charge transfer direction. In addition, the widths of the first portion 33a, the third portion 33c1, the third portion 33c2, and the second portion 33b in the signal charge transfer direction are equal to each other.

Furthermore, the third portion 33c1 has a third thickness dc1 thinner than the first thickness da, and the third portion 33c2 has a third thickness dc2 thinner than the third thickness dc1 and thicker than the second thickness db. That is, the gate insulating film 33B becomes thinner stepwise from the upstream side in the signal charge transfer direction toward the downstream direction.

<Effects>

According to the method of manufacturing the solid-state imaging apparatus 1 according to the modified example 3 of the first embodiment, effects similar to those of the solid-state imaging apparatus 1 according to the first embodiment described above can be obtained.

Furthermore, because the solid-state imaging apparatus 1 according to the modified example 3 of the first embodiment includes the third portion 33c, the potential of the modulated portion of the semiconductor layer 20 becomes lower on the downstream side in the signal charge transfer direction in a stepwise manner than that on the upstream side. Therefore, a gradient of the potential can be provided in a stepwise manner in the signal charge transfer direction. Therefore, the transfer speed can be increased. In addition, because the transfer speed can be increased, the signal charges can be prevented from stopping and the rising phenomenon can be prevented from occurring.

Note that the third portion 33c includes two portions, which are the upstream-side third portion 33c1 and the downstream-side third portion 33c2, but may include only one portion. Moreover, the third portion 33c may include three or more portions. As long as the gate insulating film 33B becomes thinner stepwise from the upstream side in the signal charge transfer direction toward the downstream direction, the number of portions included in the third portion 33c is not limited.

Furthermore, the technology of the transfer transistor 27A according to the modified example 2 of the first embodiment may be applied to the transfer transistor 27B according to the modified example 3 of the first embodiment, and the widths of the first portion 33a, the third portion 33c1, the third portion 33c2, and the second portion 33b in the signal charge transfer direction may be made different from each other.

<Method of Manufacturing Transfer Transistor>

Next, a method of manufacturing the transfer transistor 27B of the solid-state imaging apparatus 1 according to the modified example 3 of the first embodiment of the present technology is described. The method of manufacturing the transfer transistor 27B is realized by repeating the formation and etching of the mask RM plural times in the method of manufacturing the transfer transistor 27 of the solid-state imaging apparatus 1 according to the first embodiment described above.

For example, first, the first portion 33a and the third portion 33c1 of the gate insulating film 33B are formed by performing the steps shown in FIGS. 6A to 6B. Then, the third portion 33c2 and the second portion 33b are formed by repeating the formation and etching of the mask RM in FIGS. 6B and 6C plural times. Then, finally, the gate electrode 34 is formed by the steps shown in FIGS. 6D and 6E.

<Effects>

According to the method of manufacturing the solid-state imaging apparatus 1 according to the modified example 3 of the first embodiment, effects similar to those of the method of manufacturing the solid-state imaging apparatus 1 according to the first embodiment described above can be obtained.

Furthermore, in the solid-state imaging apparatus 1 according to the modified example 3 of the first embodiment, because the film thickness of the gate insulating film 33B is formed to be thinner on the downstream side in the signal charge transfer direction in a stepwise manner than that on the upstream side, the potential of the modulated portion of the semiconductor layer is lower on the downstream side in the signal charge transfer direction in a stepwise manner than that on the upstream side. Therefore, a gradient of the potential can be provided in the signal charge transfer direction. Therefore, the transfer speed can be increased. In addition, because the transfer speed can be increased, the signal charges can be prevented from stopping and the rising phenomenon can be prevented from occurring.

Note that the method of manufacturing the solid-state imaging apparatus 1 according to the modified example 3 of the first embodiment may be realized by forming the insulating material 35 and repeating the photolithography and etching plural times in the another method of manufacturing the solid-state imaging apparatus 1 according to the modified example 1 of the first embodiment described above.

### Modified Example 4 of First Embodiment

<Configuration of Solid-State Imaging Apparatus>

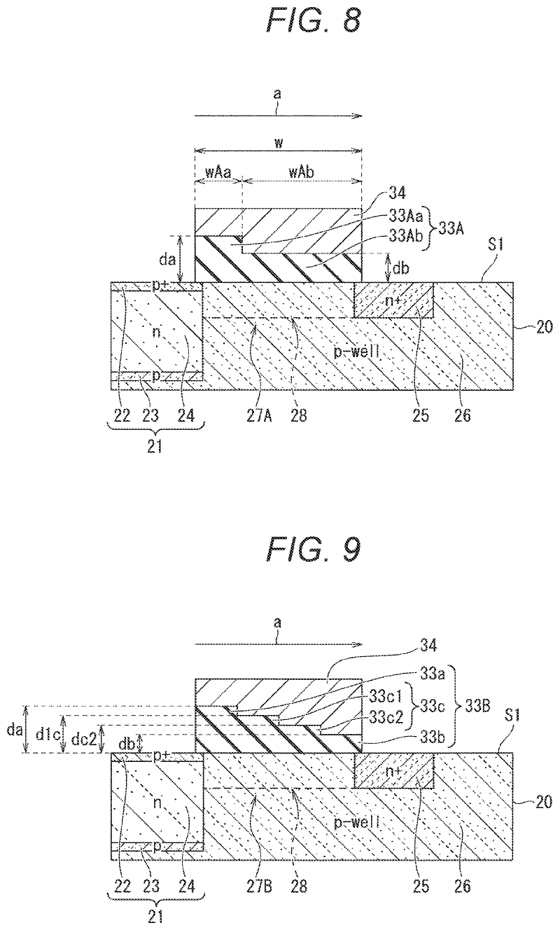

Next, a modified example 4 of the first embodiment of the present technology is described with reference to FIG. 10. The modified example 4 of the first embodiment is different from the above-described first embodiment in that the solid-state imaging apparatus 1 includes a transfer transistor 27C instead of the transfer transistor 27, and the configuration of the solid-state imaging apparatus 1 other than this is basically similar to the configuration of the solid-state imaging apparatus 1 of the above-described first embodiment. Hereinafter, the transfer transistor 27C is described.

<Configuration of Transfer Transistor>

As shown in FIG. 10, the transfer transistor 27C includes a gate insulating film 33C. The gate insulating film 33C becomes gradually thinner from the upstream side in the signal charge transfer direction toward the downstream side in the signal charge transfer direction.

Here, the film thickness of the gate insulating film 33C becomes continuously thinner from the macroscopic perspective. However, from a microscopic perspective, the gate insulating film 33C includes a large number of small steps, and thus becomes gradually thinner. The gate insulating film 33C corresponds to, for example, a case where the third portion 33c includes a large number of portions in the gate insulating film 33B according to the modified example 3 of the first embodiment described above.

<Effects>

According to the solid-state imaging apparatus 1 according to the modified example 4 of the first embodiment, effects similar to those of the solid-state imaging apparatus 1 according to the first embodiment described above can be obtained.

Furthermore, in the solid-state imaging apparatus 1 according to the modified example 4 of the first embodiment, because the film thickness of the gate insulating film 33C becomes gradually thinner from the upstream side in the signal charge transfer direction toward the downstream side in the signal charge transfer direction, the potential of the modulated portion of the semiconductor layer 20 becomes gradually lower from the upstream side in the signal charge transfer direction toward the downstream side in the signal charge transfer direction. Therefore, a gradient of the potential can be gradually provided in the signal charge transfer direction. Therefore, the transfer speed can be increased. In addition, because the transfer speed can be increased, the signal charges can be prevented from stopping and the rising phenomenon can be prevented from occurring.

<Method of Manufacturing Solid-State Imaging Apparatus>

Next, a method of manufacturing the transfer transistor 27C of the solid-state imaging apparatus 1 according to the modified example 4 of the first embodiment of the present technology is described. The method of manufacturing the transfer transistor 27C is realized by repeating the formation and etching of the mask RM plural times in the method of manufacturing the transfer transistor 27 of the solid-state imaging apparatus 1 according to the first embodiment described above.

For example, a large number of small steps of the gate insulating film 33C is formed by repeating the formation and etching of the mask RM shown in FIGS. 6B and 6C plural times.

<Effects>

Also in the method of manufacturing the solid-state imaging apparatus 1 according to the modified example 4 of the first embodiment, effects similar to those of the method of manufacturing the solid-state imaging apparatus 1 according to the first embodiment described above can be obtained.

Furthermore, in the solid-state imaging apparatus 1 according to the modified example 4 of the first embodiment, because the film thickness of the gate insulating film 33C is formed to be gradually thinner on the downstream side in the signal charge transfer direction than that on the upstream side, the potential of the modulated portion of the semiconductor layer 20 is gradually lower on the downstream side in the signal charge transfer direction than that on the upstream side. Therefore, a gradient of the potential can be provided in the signal charge transfer direction. Therefore, the transfer speed can be increased. In addition, because the transfer speed can be increased, the signal charges can be prevented from stopping and the rising phenomenon can be prevented from occurring.

### Second Embodiment

<Configuration of Solid-State Imaging Apparatus>

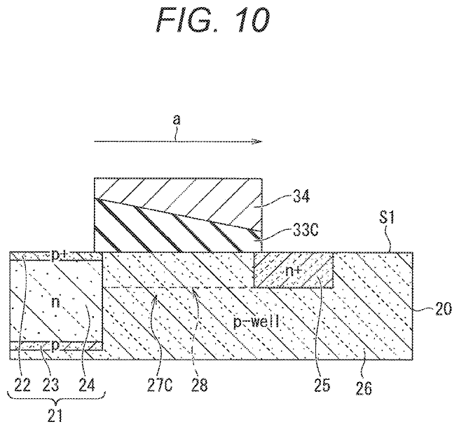

Next, a second embodiment of the present technology is described with reference to FIGS. 11A and 11B. The second embodiment is different from the above-described first embodiment in that a solid-state imaging apparatus 1 includes a transfer transistor 27D instead of the transfer transistor 27, and the configuration of the solid-state imaging apparatus 1 other than this is basically similar to the configuration of the solid-state imaging apparatus 1 of the above-described first embodiment. Hereinafter, the transfer transistor 27D is described.

<Configuration of Transfer Transistor>

As shown in FIGS. 11A and 11B, the transfer transistor 27D includes a gate electrode 38 instead of the gate electrode 34 of the first embodiment, and further includes a gate insulating film 37 instead of the gate insulating film 33 of the first embodiment.

A photoelectric conversion unit 21 and a floating diffusion region 25 are disposed on the side of a first surface S1 of a semiconductor layer 20 while being separated from each other in a direction orthogonal to the thickness direction of the semiconductor layer 20.

The gate electrode 38 includes a head part 38a provided on the first surface S1 side of the semiconductor layer 20 with the gate insulating film 37 interposed between the head part 38a and the semiconductor layer 20, and a body part 38b protruding from the head part 38a toward the second surface S2 side of the semiconductor layer 20 to the inside of the semiconductor layer 20 and having a width narrower than that of the head part 38a. The body part 38b of the gate electrode 38 has a long rod shape in the protruding direction, and as shown in FIGS. 11A and 11B, and has cross section perpendicular to the longitudinal direction smaller than the head part 38a. In addition, the body part 38b is disposed inside the semiconductor layer 20 with the gate insulating film 37 interposed between the photoelectric conversion unit 21 as the first charge accumulation region and the floating diffusion region 25 as the second charge accumulation region. In addition, the head part 38a and the body part 38b are integrally formed and include the same material. In addition, the gate insulating film 37 between the semiconductor layer 20 and the body part 38b has a thickness that is thinner on the downstream side in the signal charge transfer direction than on the upstream side in the signal charge transfer direction.

As shown in FIG. 11B, the gate insulating film 37 is provided between the gate electrode 38 and the semiconductor layer 20. The gate insulating film 37 includes a fourth portion 37a and a fifth portion 37b provided between a side surface 38b₁ of a body part 38b of the gate electrode 38 and the semiconductor layer 20, and a sixth portion 37c provided between a bottom surface 38b₂ of the body part 38b of the gate electrode 38 and the semiconductor layer 20.

As shown in FIGS. 11A and 11B, the fourth portion 37a of the gate insulating film 37 is provided on the photoelectric conversion unit 21 side and has a fourth thickness de. As shown in FIGS. 11A and 11B, the fifth portion 37b of the gate insulating film 37 is provided on the floating diffusion region 25 side and has a fifth thickness df. In addition, the fifth thickness df, which is the thickness of the fifth portion 37b of the gate insulating film 37, is thinner than the fourth thickness de of the fourth portion 37a of the gate insulating film 37. Furthermore, as shown in FIGS. 11A and 11B, the sixth portion 37c of the gate insulating film 37 has a fifth thickness df. Here, the thickness of the gate insulating film 37 is a thickness in a direction perpendicularly connecting the side surface 38b₁ or the bottom surface 38b₂ of the body part 38b of the gate electrode 38 and the semiconductor layer 20.

Referring to FIG. 11B, in the transfer transistor 27D of the second embodiment, a channel (inversion layer) is formed in the semiconductor layer 20 (well region 26) adjacent to the body part 38b of the gate electrode 38 with the gate insulating film 37 interposed between the semiconductor layer 20 and the body part 38b, and the signal charges (e−) are transferred from the photoelectric conversion unit (first charge accumulation region) 21 to the floating diffusion region (second charge accumulation region) 25 through this channel. Furthermore, in the transfer transistor 27D of the second embodiment, a channel is formed in a cap shape in the semiconductor layer 20 so as to surround the side surface 38b₁ and the bottom surface 38b₂ of the body part 38b of the gate electrode 38, and a current flows (charges move) through this channel along the first surface S1 of the semiconductor layer 20. In addition, the transfer transistor 27D of the first embodiment is also configured as an enhancement type (a normally-off type) in which the channel is formed only when a gate voltage is applied, similarly to the transfer transistor 27 of the first embodiment described above.

The signal charge transfer direction around the body part 38b of the gate electrode 38 is as indicated by an arrow a in FIG. 11A. This is because a cylindrical channel is formed for the rod-shape body part 38b. Because the gate insulating film 37 (the fifth portion 37b) on the downstream side in the signal charge transfer direction is made thinner than the gate insulating film 37 (the fourth portion 37a) on the upstream side, in the semiconductor layer 20, the portion corresponding to the fifth portion 37b of the gate insulating film 37 is modulated more strongly than the portion corresponding to the fourth portion 37a. As described above, the gate insulating film 37 may be gradually thinned with respect to the transfer route of the signal charges from the photoelectric conversion unit 21 to the floating diffusion region 25.

<Effects>

According to the solid-state imaging apparatus 1 according to the second embodiment, effects similar to those of the solid-state imaging apparatus 1 according to the first embodiment described above can be obtained.

Note that the thickness of the sixth portion 37c of the gate insulating film 37 is described as the same as the fifth thickness df of the fifth portion 37b, but may be the same as the fourth thickness de of the fourth portion 37a. In this case, it is also possible to provide a potential gradient in the signal charge transfer direction from the sixth portion 37c to the fifth portion 37b. Therefore, the transfer speed can be increased. In addition, because the transfer speed can be increased, the signal charges can be prevented from stopping and the rising phenomenon can be prevented from occurring.

Furthermore, as shown in FIG. 11B, also in the gate insulating film 37 between the head part 38a of the gate electrode 38 and the semiconductor layer 20, the film thickness on the floating diffusion region 25 side may be made thinner than the film thickness on the photoelectric conversion unit 21 side.

### Modified Example of Second Embodiment

<Configuration of Solid-State Imaging Apparatus>

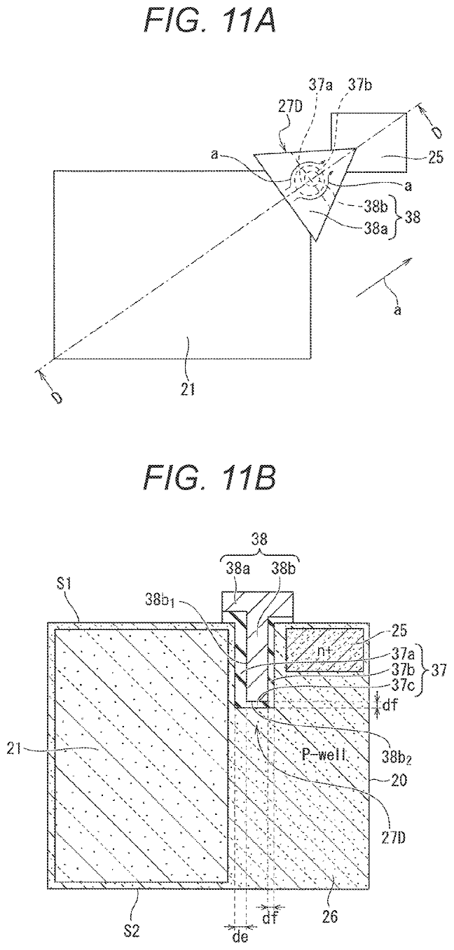

Next, a modified example of the second embodiment is described with reference to FIGS. 12A and 12B. The modified example of the second embodiment is different from the above-described second embodiment in that the solid-state imaging apparatus 1 includes a transfer transistor 27E instead of the transfer transistor 27D and has a photoelectric conversion unit embedded structure in which the photoelectric conversion unit 21 is formed in a depth of the semiconductor layer 20 in order to enlarge the area of the pixel transistor and the like, and the configuration of the solid-state imaging apparatus 1 other than these is basically similar to the configuration of the solid-state imaging apparatus 1 of the above-described second embodiment. Hereinafter, the transfer transistor 27E is described.

<Configuration of Transfer Transistor>

As shown in FIGS. 12A and 12B, the transfer transistor 27E includes the gate electrode 38 similarly to the second embodiment described above. In addition, the transfer transistor 27E includes a gate insulating film 37E instead of the gate insulating film 37 of the second embodiment described above. Furthermore, because the photoelectric conversion unit 21 has a photoelectric conversion unit embedded structure, the gate electrode 38 and the gate insulating film 37E are provided above the photoelectric conversion unit 21, that is, on the first surface S1 side of the photoelectric conversion unit 21. In other words, the floating diffusion region 25 is provided on the first surface S1 side of the semiconductor layer 20, and the photoelectric conversion unit 21 is provided at a position deeper than the floating diffusion region 25 from the first surface S1 of the semiconductor layer 20. In addition, the transfer transistor 27E is disposed in a region overlapping the photoelectric conversion unit 21 in plan view.

The gate electrode 38 includes the head part 38a provided on the first surface S1 side of the semiconductor layer 20 with the gate insulating film 37 interposed between the head part 38a and the semiconductor layer 20, and the body part 38b protruding from the head part 38a to the inside of the semiconductor layer 20 with the gate insulating film 37 interposed between the body part 38b and the semiconductor layer 20 in a region overlapping the photoelectric conversion unit 21 in plan view. In addition, the gate insulating film 37 between the body part 38b and the semiconductor layer 20 has a thickness that is thinner on the downstream side in the signal charge transfer direction than on the upstream side in the signal charge transfer direction.

As shown in FIG. 12B, the gate insulating film 37E is provided between the gate electrode 38 and the semiconductor layer 20. The gate insulating film 37 includes a fourth portion 37a and a fifth portion 37b provided between a side surface 38b₁ of a body part 38b of the gate electrode 38 and the semiconductor layer 20, and a sixth portion 37c provided between a bottom surface 38b₂ of the body part 38b of the gate electrode 38 and the semiconductor layer 20. As shown in FIGS. 11A and 11B, the fourth portion 37a of the gate insulating film 37 is provided on the photoelectric conversion unit 21 side and has the fifth thickness df. As shown in FIGS. 11A and 11B, the fifth portion 37b of the gate insulating film 37 is provided on the floating diffusion region 25 side and has a fifth thickness df. That is, the fourth portion 37a and the fifth portion 37b are configured to have the same thickness and have the fifth thickness df. The fourth portion 37a and the fifth portion 37b may be collectively referred to as a seventh portion 37d. Furthermore, as shown in FIGS. 11A and 11B, the sixth portion 37c of the gate insulating film 37 has the fourth thickness de. In addition, the fifth thickness df, which is the thickness of the fourth portion 37a and the fifth portion 37b, is thinner than the fourth thickness de, which is the thickness of the sixth portion 37c of the gate insulating film 37E.

The signal charge transfer direction around the gate electrode 38 is as indicated by an arrow a in FIG. 12B. Because the seventh portion 37d of the gate insulating film 37E on the downstream side in the signal charge transfer direction is made thinner than the sixth portion 37c of the gate insulating film 37E on the upstream side, in the semiconductor layer 20, the portion corresponding to the seventh portion 37d is modulated more strongly than the portion corresponding to the sixth portion 37c. As described above, the gate insulating film 37E may be gradually thinned with respect to the transfer route of the signal charges from the photoelectric conversion unit 21 to the floating diffusion region 25.

Referring to FIG. 12B, in the transfer transistor 27E of the modified example of the second embodiment, a channel (inversion layer) is formed in the semiconductor layer 20 (well region 26) adjacent to the body part 38b of the gate electrode 38 with the gate insulating film 37E interposed between the semiconductor layer 20 and the body part 38b, and the signal charges (e−) are transferred from the photoelectric conversion unit (first charge accumulation region) 21 to the floating diffusion region (second charge accumulation region) 25 through this channel. Furthermore, in the transfer transistor 27E of the modified example of the second embodiment, a channel is formed in a cap shape in the semiconductor layer 20 so as to surround the side surface 38b₁ and the bottom surface 38b₂ of the body part 38b of the gate electrode 38, and a current flows (signal charges move) through this channel along the thickness direction of the semiconductor layer 20.

In addition, the transfer transistor 27E of the first embodiment is also configured as an enhancement type (normally-off type) in which the channel is formed only when a gate voltage is applied, similarly to the transfer transistor 27 of the first embodiment described above.

<Effects>

According to the solid-state imaging apparatus 1 according to the modified example of the second embodiment, effects similar to those of the solid-state imaging apparatus 1 according to the second embodiment described above can be obtained.

Note that the thickness of the fourth portion 37a of the gate insulating film 37E is described as the same as the fifth thickness df of the fifth portion 37b, but may be the same as the fourth thickness de of the sixth portion 37c. In this case, it is also possible to provide a potential gradient in the signal charge transfer direction from the fourth portion 37a to the fifth portion 37b. Therefore, the transfer speed can be increased. In addition, because the transfer speed can be increased, the signal charges can be prevented from stopping and the rising phenomenon can be prevented from occurring.

In addition, in FIG. 12B, the thicknesses of the first portion 33a and the second portion 33b of the gate insulating film 33 are drawn to be equal, but the present invention is not limited thereto, and the thickness of the second portion 33b may be thinner than the thickness of the first portion 33a.

### Third Embodiment

<Configuration of Solid-State Imaging Apparatus>

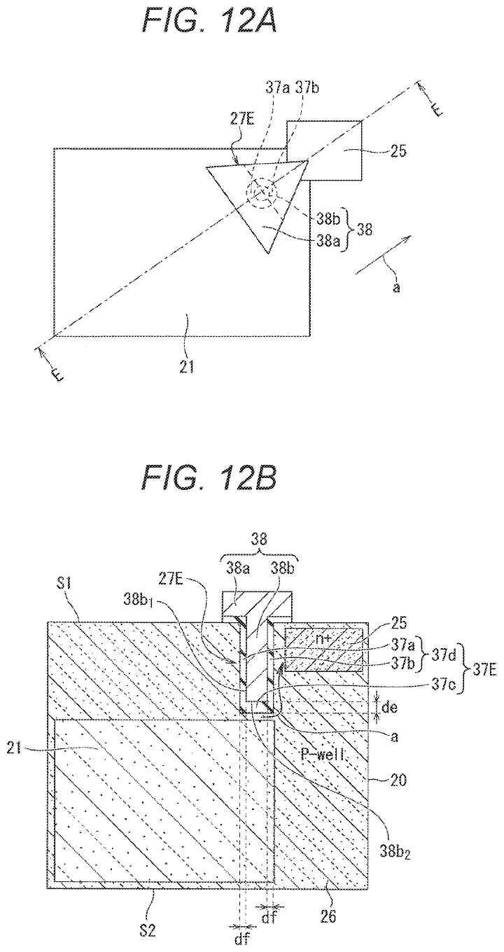

Next, a third embodiment of the present technology is described with reference to FIG. 13. The third embodiment is different from the above-described first embodiment in that a solid-state imaging apparatus 1 includes a transfer transistor 27F instead of the transfer transistor 27, and the configuration of the solid-state imaging apparatus 1 other than this is basically similar to the configuration of the solid-state imaging apparatus 1 of the above-described first embodiment. Hereinafter, the transfer transistor 27F is described.

<Configuration of Transfer Transistor>

The transfer transistor 27F is different from the transfer transistor 27 of the first embodiment in that, as shown in FIG. 13, a gate insulating film 33F included therein has a uniform film thickness and a region having a high dielectric constant is provided on the side of a floating diffusion region 25. That is, the transfer transistor 27F has a structure in which the dielectric constant of the gate insulating film 33F has locality.

The gate insulating film 33F includes an eighth portion 33Fa having a first relative dielectric constant Ea and a ninth portion 33Fb having a second relative dielectric constant Eb higher than the first relative dielectric constant Ea. In addition, the ninth portion 33Fb is provided on the downstream side of the gate insulating film 33F in the signal charge transfer direction, that is, on the floating diffusion region 25 side. That is, the relative dielectric constant of the gate insulating film 33F is higher on the downstream side in the signal charge transfer direction, that is, on the floating diffusion region 25 side than on the upstream side in the signal charge transfer direction, that is, on the side of a photoelectric conversion unit 21.

Here, a capacitance Cₒₓ of the gate insulating film 33F is generally given by the following Formula 1. ε₀ₓ represents a relative dielectric constant of the insulating film, ε₀ represents a dielectric constant of vacuum, S represents a gate area, and d represents a thickness of the insulating film.

$${C}_{ox} = {ε}_{ox} {ε}_{o} \frac{S}{d} \qquad [ Mathematical formula 1 ]$$

In order to enhance the modulation on the floating diffusion region 25 side more than on the photoelectric conversion unit 21 side to improve the transfer of signal charges, it is necessary to increase a capacitance C on the floating diffusion region 25 side more than on the photoelectric conversion unit 21 side. Then, in order to enhance the capacitance C on the floating diffusion region 25 side more than on the photoelectric conversion unit 21 side, it is necessary to increase the relative dielectric constant of the insulating film on the floating diffusion region 25 side more than on the photoelectric conversion unit 21 side.

The eighth portion 33Fa of the gate insulating film 33F includes, for example, a silicon oxide (SiO₂) film, and the ninth portion 33Fb includes, for example, a silicon oxynitride film (SiON). In addition, a silicon oxide film which is the eighth portion 33Fa is interposed between the ninth portion 33Fb and a semiconductor layer 20.

<Effects>

According to the solid-state imaging apparatus 1 according to the third embodiment, effects similar to those of the solid-state imaging apparatus 1 according to the first embodiment described above can be obtained.

<Method of Manufacturing Transfer Transistor>

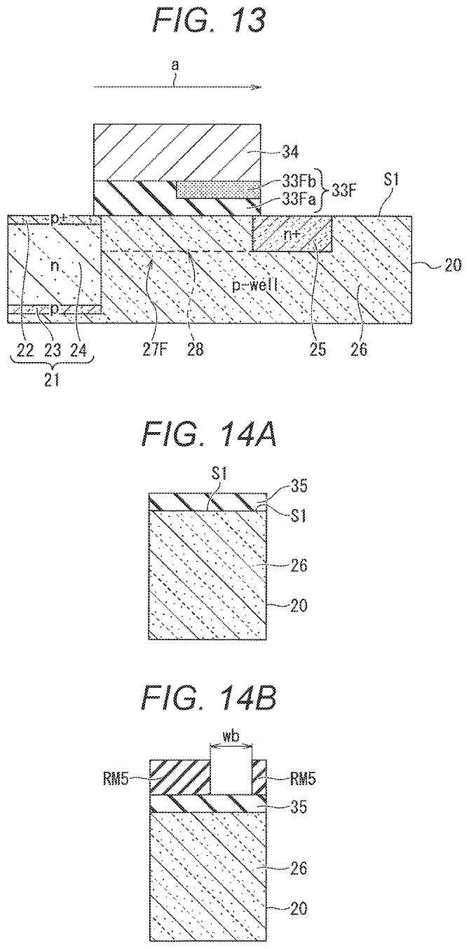

Next, a method of manufacturing the transfer transistor 27F of the solid-state imaging apparatus 1 according to the third embodiment of the present technology is described with reference to FIGS. 14A to 14E. In FIGS. 14A to 14E, it is assumed that the photoelectric conversion unit 21 and the floating diffusion region 25 are already formed in the semiconductor layer 20, and a detailed illustration of the inside of the semiconductor layer 20 is omitted. Furthermore, the cross sections shown in FIGS. 14A to 14E are the same as the cross section shown in FIG. 5B.

First, as shown in FIG. 14A, an insulating material 35 is formed on a first surface S1 of the semiconductor layer 20. The insulating material 35 is a material constituting the gate insulating film 33F. The insulating material 35 is formed by, for example, deposition.

Next, as shown in FIG. 14B, a mask RM5 is formed on the insulating material 35 by a known photolithography technique. The mask RM5 is a resist mask, and has an opening whose width in the signal charge transfer direction is the same as a width wb of the ninth portion 33Fb.

Next, as shown in FIG. 14C, plasma nitriding is performed on the insulating material 35 at the opening portion of the mask RM5 having the width wb to form a silicon oxynitride film. Thereafter, the mask RM5 is removed. As a result, the ninth portion 33Fb is formed. Then, the relative dielectric constant of the ninth portion 33Fb on the downstream side in the signal charge transfer direction is formed to be larger than the relative dielectric constant of the eighth portion 33Fa on the upstream side in the signal charge transfer direction.

Next, as shown in FIG. 14D, a gate material 36 is formed on the insulating material 35, and subsequently, a mask RM6 is formed on the gate material 36 by a known photolithography technique. The gate material 36 is a material constituting the gate electrode 34. Then, using the mask RM6 as an etching mask, the gate material 36 and the insulating material 35 are sequentially patterned to form the gate electrode 34 and the gate insulating film 33F as shown in FIG. 14E.

<Effects>

Also in the method of manufacturing the solid-state imaging apparatus 1 according to the third embodiment, effects similar to those of the method of manufacturing the solid-state imaging apparatus 1 according to the first embodiment described above can be obtained.

Note that the silicon oxynitride film is formed by plasma nitriding, but may be formed by chemical vapor deposition (CVD) or thermal oxynitriding.

### Modified Example of Third Embodiment

<Configuration of Solid-State Imaging Apparatus>

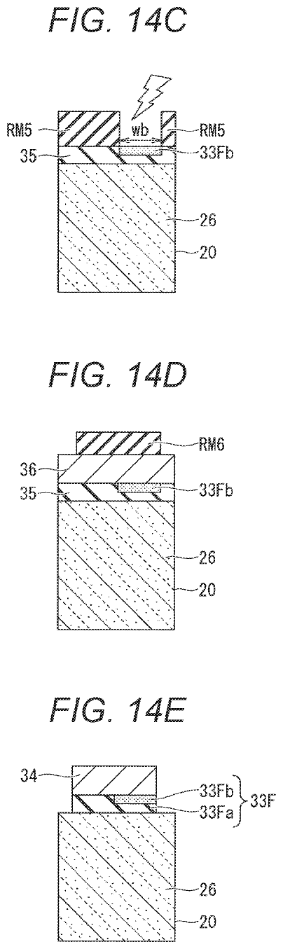

Next, a modified example of the third embodiment of the present technology is described with reference to FIG. 15. The modified example of the third embodiment is different from the above-described third embodiment in that the solid-state imaging apparatus 1 includes a transfer transistor 27G instead of the transfer transistor 27F, and the configuration of the solid-state imaging apparatus 1 other than this is basically similar to the configuration of the solid-state imaging apparatus 1 of the above-described third embodiment. Hereinafter, the transfer transistor 27G is described.

<Configuration of Transfer Transistor>

As shown in FIG. 15, the transfer transistor 27G is different from the transfer transistor 27F of the third embodiment in that a gate insulating film 33G included therein has a ninth portion 33Gb including alumina (Al₂O₃) instead of a silicon oxynitride film (SiON).

As shown in FIG. 15, the gate insulating film 33G includes an eighth portion 33Ga having a first relative dielectric constant Ea and a ninth portion 33Gb having a second relative dielectric constant Eb higher than the first relative dielectric constant Ea. In addition, the ninth portion 33Gb is provided on the downstream side of the gate insulating film 33G in the signal charge transfer direction, that is, on the floating diffusion region 25 side. That is, the relative dielectric constant of the gate insulating film 33G is higher on the downstream side in the signal charge transfer direction, that is, on the floating diffusion region 25 side than on the upstream side in the signal charge transfer direction, that is, on the photoelectric conversion unit 21 side. Moreover, as shown in FIG. 15, the ninth portion 33Gb is provided between the semiconductor layer 20 and the gate electrode 34.

The eighth portion 33Ga of the gate insulating film 33G includes, for example, a silicon oxide (SiO₂) film, and the ninth portion 33Gb includes, for example, alumina (Al₂O₃).

<Effects>

According to the solid-state imaging apparatus 1 according to the modified example of the third embodiment, effects similar to those of the solid-state imaging apparatus 1 according to the third embodiment described above can be obtained.

Note that the material constituting the ninth portion 33Gb is not limited to alumina, and may be another high dielectric constant gate insulating film (High-k film). Here, the high dielectric constant gate insulating film is a generic term for a material having a relative dielectric constant higher than that of silicon oxide. The high dielectric constant gate insulating film includes the above-described alumina, for example, a hafnium material such as hafnium oxide (HfO₂), and a material such as zirconium oxide (ZrO₂), but is not limited to these examples.

<Method of Manufacturing Transfer Transistor>

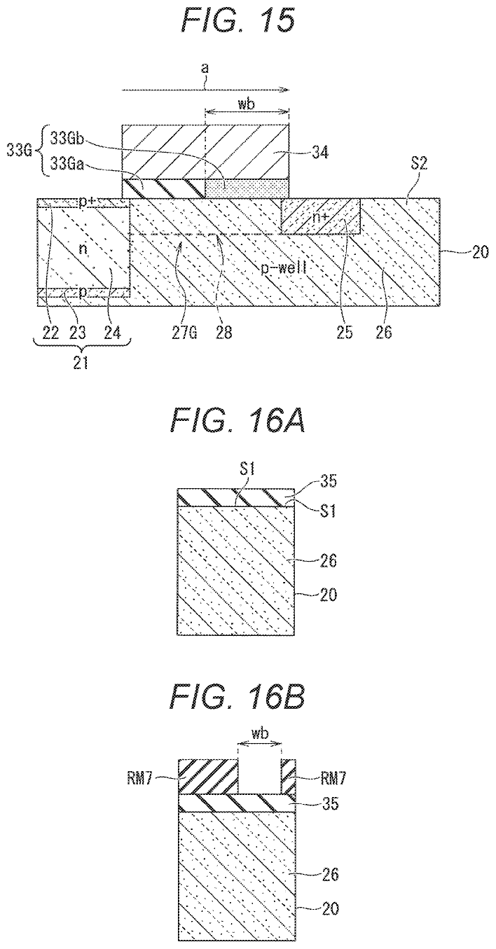

Next, a method of manufacturing the transfer transistor 27G of the solid-state imaging apparatus 1 according to the modified example of the third embodiment is described with reference to FIGS. 16A to 16E. In FIGS. 16A to 16E, it is assumed that the photoelectric conversion unit 21 and the floating diffusion region 25 are already formed in the semiconductor layer 20, and a detailed illustration of the inside of the semiconductor layer 20 is omitted. Furthermore, the cross sections shown in FIGS. 16A to 16E are the same as the cross section shown in FIG. 5B.

First, as shown in FIG. 16A, the insulating material 35 is formed on the first surface S1 of the semiconductor layer 20. The insulating material 35 is a material constituting the gate insulating film 33F. The insulating material 35 is formed by, for example, deposition.

Next, as shown in FIG. 16B, a mask RM7 is formed on the insulating material 35 by a known photolithography technique. The mask RM7 is a resist mask, and has an opening whose width in the signal charge transfer direction is the same as a width wb of the ninth portion 33Gb. Subsequently, the insulating material 35 exposed from the opening having the width wb of the mask RM is removed by etching.

Next, as shown in FIG. 16C, an alumina material 39 is deposited. Thereafter, the mask RM7 and the alumina material 39 on the mask RM7 are selectively removed using the lift-off method. As a result, as shown in FIG. 16D, the ninth portion 33Gb is formed. Then, the relative dielectric constant of the ninth portion 33Gb on the downstream side in the signal charge transfer direction is formed to be larger than the relative dielectric constant of the eighth portion 33Ga on the upstream side in the signal charge transfer direction.

Next, as shown in FIG. 16E, a gate material 36 is formed on the insulating material 35, and subsequently, a mask RM8 is formed on the gate material 36 by a known photolithography technique. The gate material 36 is a material constituting the gate electrode 34. Then, using the mask RM8 as an etching mask, the gate material 36 and the insulating material 35 are sequentially patterned to form the gate electrode 34 and the gate insulating film 33G as shown in FIG. 16F.

<Effects>

Also in the method of manufacturing the solid-state imaging apparatus 1 according to the modified example of the third embodiment, effects similar to those of the method of manufacturing the solid-state imaging apparatus 1 according to the third embodiment described above can be obtained.

### Fourth Embodiment

<Configuration of Solid-State Imaging Apparatus>

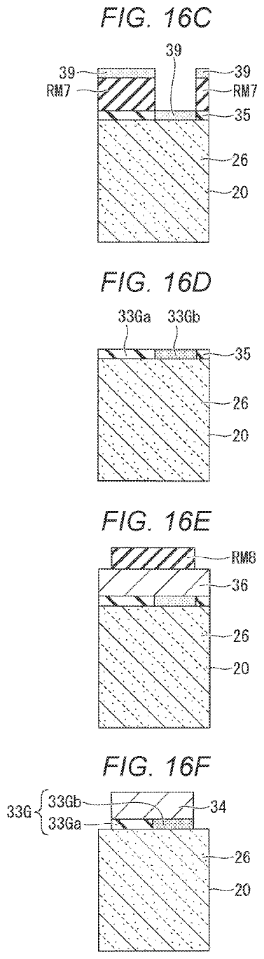

Next, a fourth embodiment of the present technology is described with reference to FIGS. 17A and 17B. The fourth embodiment is different from the first embodiment described above in that the solid-state imaging apparatus 1 has a global shutter function. Other configurations of the solid-state imaging apparatus 1 are basically similar to those of the solid-state imaging apparatus 1 of the first embodiment described above. Hereinafter, the global shutter is described.

<Configuration of Global Shutter>

As shown in FIGS. 17A and 17B, the global shutter includes a first transfer transistor 27H, a memory region 29, and a second transfer transistor 27I between a photoelectric conversion unit 21 and a floating diffusion region 25. The first transfer transistor 27H and the second transfer transistor 27I have the same structure as the transfer transistor 27 of the first embodiment described above. The configurations of gate electrodes 341 and 342 of the first transfer transistor 27H and the second transfer transistor 27I are the same as the configuration of the gate electrode 34 of the transfer transistor 27 of the first embodiment. In addition, the configurations of gate insulating films 331 and 332 are the same as those of the gate insulating film 33 of the transfer transistor 27 of the first embodiment. The memory region 29 is formed in the semiconductor layer 20, that is, embedded in the semiconductor layer 20. The memory region 29 is a semiconductor region of the second conductivity type (for example, an n-type) and is in a floating state.

The photoelectric conversion unit 21 is a first charge accumulation region that functions as a source region of the first transfer transistor 27H. In addition, the memory region 29 is a second charge accumulation region that functions as a drain region of the first transfer transistor 27H.

Furthermore, the memory region 29 is the first charge accumulation region that functions as a source region of the second transfer transistor 27I. In addition, the floating diffusion region 25 is the second charge accumulation region that functions as a drain region of the second transfer transistor 27I.

The first transfer transistor 27H transfers the signal charges from the photoelectric conversion unit 21 functioning as a source region to the memory region 29 functioning as a drain region. When the gate-source voltage of the first transfer transistor 27H is set to the high (H) level, a part of a well region 26 of the first conductivity type is inverted to the second conductivity type along the gate electrode 341 to become a channel. Then, the photoelectric conversion unit 21 and the memory region 29 are connected by the channel. As a result, the signal charges flow from the photoelectric conversion unit 21 to the memory region 29.

Alternatively, when the gate-source voltage of the first transfer transistor 27H is set to the low (L) level, the photoelectric conversion unit 21 and the memory region 29 are completely separated from each other, that is, the potential is separated, and the signal charges are not transferred.

Furthermore, the signal charge transfer direction is a direction from the photoelectric conversion unit 21 (first charge accumulation region) functioning as the source region toward the memory region 29 (second charge accumulation region) functioning as the drain region, that is, a direction indicated by an arrow a.

The second transfer transistor 27I transfers the signal charges from the memory region 29 functioning as the source region to the floating diffusion region 25 functioning as the drain region. When the gate-source voltage of the second transfer transistor 27I is set to the high (H) level, a part of the well region 26 of the first conductivity type is inverted to the second conductivity type along the gate electrode 341 to become a channel. Then, the memory region 29 and the floating diffusion region 25 are connected to each other by the channel. As a result, the signal charges flow from the memory region 29 to the floating diffusion region 25. Furthermore, when the gate-source voltage of the second transfer transistor 27I is set to the low (L) level, the memory region 29 and the floating diffusion region 25 are completely separated from each other, that is, the potential is separated, and the signal charges are not transferred.

Furthermore, the signal charge transfer direction is a direction from the memory region 29 (first charge accumulation region) functioning as the source region toward the floating diffusion region 25 (second charge accumulation region) functioning as the drain region, that is, a direction indicated by the arrow a.

A function of such a global shutter is described. First, all pixels 9 are exposed at the same timing, and the photoelectric conversion unit 21 accumulates generated signal charges. All the signal charges accumulated in the photoelectric conversion unit 21 are transferred to the memory region 29 at the same timing, and the memory region 29 accumulates the transferred signal charges. The signal charges accumulated in the memory region 29 are sequentially transferred to the floating diffusion region 25 at different timings.

<Effects>

According to the solid-state imaging apparatus 1 according to the fourth embodiment, effects similar to those of the solid-state imaging apparatus 1 according to the first embodiment described above can be obtained.

Note that the configurations of the gate electrode and the gate insulating film of the modified examples of the first embodiment, the second embodiment and the modified example thereof, and the third embodiment and the modified example thereof may be applied to the first transfer transistor 27H and the second transfer transistor 27I of the fourth embodiment.

### Fifth Embodiment

<Configuration of Solid-State Imaging Apparatus>

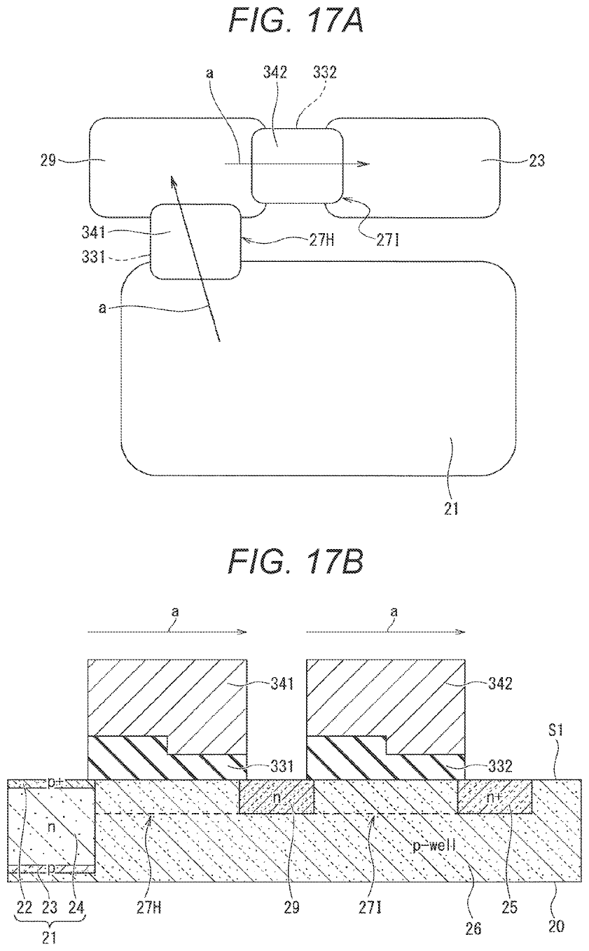

Next, a fifth embodiment of the present technology is described with reference to FIG. 18. The fifth embodiment is different from the above-described first embodiment in that a solid-state imaging apparatus 1 includes a transfer transistor 27J instead of the transfer transistor 27, and the configuration of the solid-state imaging apparatus 1 other than this is basically similar to the configuration of the solid-state imaging apparatus 1 of the above-described first embodiment. Hereinafter, the transfer transistor 27J is described.

<Configuration of Transfer Transistor>

As shown in FIG. 18, the transfer transistor 27J includes two-divided gate electrodes 343 and 344 and a gate insulating film 33J having a uniform thickness and a uniform relative dielectric constant. The gate electrode 343 is provided on the side of a photoelectric conversion unit 21, that is, the upstream side in the signal charge transfer direction, and the gate electrode 344 is provided on the side of a floating diffusion region 25, that is, the downstream side in the signal charge transfer direction.

When a voltage between the gate electrode 343 of the transfer transistor 27J and a source (the photoelectric conversion unit 21) is set to a first high (H1) level, a part of a well region 26 of the first conductivity type is inverted to the second conductivity type along the gate electrode 343 to become a channel 281.

When a voltage between the gate electrode 344 of the transfer transistor 27J and the source (the photoelectric conversion unit 21) is set to a second high (H2) level higher than the first high level, a part of the well region 26 of the first conductivity type is inverted to the second conductivity type along the gate electrode 344 to become a channel 282.

Because the second high level is higher than the first high level, in the semiconductor layer 20, a portion corresponding to the gate electrode 344 is modulated more strongly than a portion corresponding to the gate electrode 343. As described above, in the fifth embodiment of the present technology, the transfer gradient of the signal charges is adjusted by adjusting the on-voltage.

<Effects>

According to the solid-state imaging apparatus 1 according to the fifth embodiment, effects similar to those of the solid-state imaging apparatus 1 according to the first embodiment described above can be obtained.

Note that, in the solid-state imaging apparatus 1 of the first embodiment and the modified examples thereof, the second embodiment and the modified example thereof, the third embodiment and the modified example thereof, the fourth embodiment, and the fifth embodiment, the support substrate 40 is described as a substrate for securing the strength of the semiconductor layer 20, but the present invention is not limited thereto. On the support substrate 40, for example, an active element constituting at least a part of the circuit or the element, the memory region, or the like illustrated in FIGS. 1 and 2 may be formed.

### Sixth Embodiment: Electronic Device

Next, an electronic device according to a sixth embodiment of the present technology is described. FIG. 19 is a schematic configuration diagram of an electronic device 100 according to the sixth embodiment of the present technology.

The electronic device 100 according to the sixth embodiment includes a solid-state imaging apparatus 101, the optical lens 102, a shutter device 103, a drive circuit 104, and a signal processing circuit 105. The electronic device 100 according to the sixth embodiment shows an embodiment in a case where the solid-state imaging apparatus 1 according to the first embodiment of the present technology is used for an electronic device (for example, a camera) as the solid-state imaging apparatus 101.

The optical lens 102 forms an image of image light (incident light 106) from a subject on an imaging surface of the solid-state imaging apparatus 101. As a result, signal charges are accumulated in the solid-state imaging apparatus 101 over a certain period. The shutter device 103 controls a light irradiation period and a light shielding period for the solid-state imaging apparatus 101. The drive circuit 104 supplies a drive signal for controlling the transfer operation of the solid-state imaging apparatus 101 and the shutter operation of the shutter device 103. A signal of the solid-state imaging apparatus 101 is transferred by a drive signal (timing signal) supplied from the drive circuit 104. The signal processing circuit 105 performs various types of signal processing on a signal (pixel signal) output from the solid-state imaging apparatus 101. The video signal subjected to the signal processing is stored in a storage medium such as a memory or output to a monitor.

Note that the electronic device 100 to which the solid-state imaging apparatus 1 can be applied is not limited to a camera, and can also be applied to other electronic devices. For example, the solid-state imaging apparatus may be applied to an imaging apparatus such as a camera module for a mobile device such as a mobile phone or a tablet terminal.

Furthermore, in the sixth embodiment, as the solid-state imaging apparatus 101, the solid-state imaging apparatus 1 according to the first embodiment is used for an electronic device, but another configuration may be used. For example, the solid-state imaging apparatus 1 according to the second embodiment or the solid-state imaging apparatus 1 according to the modified examples may be used for an electronic device.

Note that the solid-state imaging apparatus 1 according to the modified example of the first embodiment, the second embodiment and the modified example thereof, the third embodiment and the modified example thereof, the fourth embodiment, and the fifth embodiment may be applied to the solid-state imaging apparatus 101 according to the sixth embodiment.

Note that the present technology can have the following configurations.

(1)

A solid-state imaging apparatus including:
a first charge accumulation region and a second charge accumulation region provided separated from each other in a semiconductor layer; and
a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel, in which
the gate insulating film has a thickness that is thinner on a downstream side in a transfer direction of the signal charges than on an upstream side in the transfer direction of the signal charges.

(2)

The solid-state imaging apparatus according to (1) described above, in which the gate insulating film includes a first portion provided on the upstream side in the transfer direction of the signal charges and having a first thickness, and a second portion provided on the downstream side in the transfer direction of the signal charges and having a second thickness thinner than the first thickness.

(3)

The solid-state imaging apparatus according to (1) or (2) described above, in which
the gate insulating film includes the first portion provided on the upstream side in the transfer direction of the signal charges and having the first thickness, and the second portion provided on the downstream side in the transfer direction of the signal charges and having the second thickness thinner than the first thickness, and
the first portion in the transfer direction of the signal charges has a width that is equal to a width of the second portion in the transfer direction of the signal charges.

(4)

The solid-state imaging apparatus according to (1) or (2) described above, in which
the gate insulating film includes the first portion provided on the upstream side in the transfer direction of the signal charges and having the first thickness, and the second portion provided on the downstream side in the transfer direction of the signal charges and having the second thickness thinner than the first thickness, and
the first portion in the transfer direction of the signal charges has a width that is different from a width of the second portion in the transfer direction of the signal charges.

(5)

The solid-state imaging apparatus according to any one of (1) to (4) described above, in which the gate insulating film includes the first portion provided on the upstream side in the transfer direction of the signal charges and having the first thickness, the second portion provided on the downstream side in the transfer direction of the signal charges and having the second thickness thinner than the first thickness, and a third portion provided between the first portion and the second portion and having a third thickness thinner than the first thickness and thicker than the second thickness.

(6)

The solid-state imaging apparatus according to (1) described above, in which the gate insulating film becomes gradually thinner from the upstream side in the transfer direction of the signal charges toward the downstream side in the transfer direction of the signal charges.

(7)

The solid-state imaging apparatus according to any one of (1) to (6) described above, in which
the first charge accumulation region and the second charge accumulation region are disposed side by side on a side of a first surface of the semiconductor layer in a direction orthogonal to a thickness direction of the semiconductor layer,
the gate electrode includes a head part provided on the side of the first surface of the semiconductor layer with the gate insulating film interposed between the head part and the semiconductor layer, and a body part protruding from the head part to an inside of the semiconductor layer with the gate insulating film interposed between the body part and the semiconductor layer, between the first charge accumulation region and the second charge accumulation region, and
the gate insulating film has a thickness between the body part and the semiconductor layer, the thickness being thinner on the downstream side in the transfer direction of the signal charges than on the upstream side in the transfer direction of the signal charges.

(8)

The solid-state imaging apparatus according to (7) described above, in which
the gate insulating film includes a fourth portion and a fifth portion provided between a side surface of the body part and the semiconductor layer,
the fourth portion is provided on a side of the first charge accumulation region, and the fifth portion is provided on a side of the second charge accumulation region, and
the fifth portion has a fifth thickness thinner than a fourth thickness that is a thickness of the fourth portion.

(9)

The solid-state imaging apparatus according to (1) described above, in which
the second charge accumulation region is disposed on a side of a first surface of the semiconductor layer,
the first charge accumulation region is disposed on a position deeper than the second charge accumulation region from the first surface of the semiconductor layer,
the gate electrode includes a head part provided on the side of the first surface of the semiconductor layer with the gate insulating film interposed between the head part and the semiconductor layer, and a body part protruding from the head part to an inside of the semiconductor layer with the gate insulating film interposed between the body part and the semiconductor layer, in a region where the gate electrode overlaps the first charge accumulation region in plan view, and
the gate insulating film has a thickness between the body part and the semiconductor layer, the thickness being thinner on the downstream side in the transfer direction of the signal charges than on the upstream side in the transfer direction of the signal charges.

(10)

The solid-state imaging apparatus according to (9) described above, in which
the gate insulating film includes a seventh portion provided between a side surface of the body part and the semiconductor layer, and a sixth portion provided between a bottom surface of the body part and the semiconductor layer, and
the sixth portion has a fifth thickness thinner than a fourth thickness that is a thickness of the seventh portion.

(11)

A solid-state imaging apparatus including:
a first charge accumulation region and a second charge accumulation region provided separated from each other in a semiconductor layer; and
a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel, in which
the gate insulating film includes an eighth portion having a first relative dielectric constant and a ninth portion having a second relative dielectric constant higher than the first relative dielectric constant, and
the ninth portion is provided on a downstream side in a transfer direction of the signal charges in the gate insulating film.

(12)

The solid-state imaging apparatus according to (11) described above, in which the eighth portion includes, for example, a silicon oxide film, and the ninth portion includes a silicon oxynitride film.

(13)

The solid-state imaging apparatus according to (11) described above, in which the eighth portion includes, for example, a silicon oxide film, and the ninth portion includes a high dielectric constant gate insulating film.

(14)

A method of manufacturing a solid-state imaging apparatus, the method including:
forming a first charge accumulation region and a second charge accumulation region in a semiconductor layer;
forming a transfer transistor having a gate electrode and a gate insulating film and configured to transfer signal charges accumulated in the first charge accumulation region to the second charge accumulation region; and
forming the gate insulating film having a thickness that is thinner on a downstream side in a transfer direction of the signal charges than a thickness of the gate insulating film on an upstream side in the transfer direction of the signal charges.

(15)

A method of manufacturing a solid-state imaging apparatus, the method including:
forming a first charge accumulation region and a second charge accumulation region in a semiconductor layer;
forming a transfer transistor having a gate electrode and a gate insulating film and configured to transfer signal charges accumulated in the first charge accumulation region to the second charge accumulation region; and
forming the gate insulating film having a larger relative dielectric constant on a downstream side in a transfer direction of the signal charges than a relative dielectric constant of the gate insulating film on an upstream side in the transfer direction of the signal charges.

(16)

An electronic device including:
a solid-state imaging apparatus;
an optical lens that forms an image of image light from a subject on an imaging surface of the solid-state imaging apparatus; and
a signal processing circuit that performs signal processing on a signal output from the solid-state imaging apparatus, in which
the solid-state imaging apparatus includes:
a first charge accumulation region and a second charge accumulation region provided separated from each other in a semiconductor layer; and
a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel, and
the gate insulating film of the solid-state imaging apparatus has a thickness that is thinner on a downstream side in a transfer direction of the signal charges than on an upstream side in the transfer direction of the signal charges.

(17)

An electronic device including:
a solid-state imaging apparatus;
an optical lens that forms an image of image light from a subject on an imaging surface of the solid-state imaging apparatus; and
a signal processing circuit that performs signal processing on a signal output from the solid-state imaging apparatus, in which
the solid-state imaging apparatus includes:
a first charge accumulation region and a second charge accumulation region provided separated from each other in a semiconductor layer; and
a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel,
the gate insulating film includes an eighth portion having a first relative dielectric constant and a ninth portion having a second relative dielectric constant higher than the first relative dielectric constant, and
the ninth portion is provided on a downstream side in a transfer direction of the signal charges in the gate insulating film.

### REFERENCE SIGNS LIST

1 Solid-state imaging apparatus
2 Semiconductor chip
3 Pixel region
4 Vertical drive circuit
5 Column signal processing circuit
6 Horizontal drive circuit
7 Output circuit
8 Control circuit
9 Pixel
10 Pixel drive wiring line
11 Vertical signal line
12 Horizontal signal line
13 Fixed charge film
14 Insulating film
15 Light shielding film
16 Planarization film
17 Color filter layer
18 Microlens
20 Semiconductor layer
21 Photoelectric conversion unit
22, 23, 24 Semiconductor region
25 Floating diffusion region
26 Well region
27, 27A, 27B, 27C, 27D, 27E, 27F, 27G, 27J Transfer transistor
27H First transfer transistor
27I Second transfer transistor
28, 281, 282 Channel
29 Memory region
30 Multilayer wiring layer
31 Interlayer insulating film
32 Wiring line
33, 33A, 33B Gate insulating film
33a, 33Aa First portion
33b, 33Ab Second portion
33c, 33c1, 33c2 Third portion
34, 38 Gate electrode
35 Insulating material
36 Gate material
37 Gate insulating film
37a Fourth portion
37b Fifth portion
37c Sixth portion
37d Seventh portion
38 Gate electrode
38a Head part
38b Body part
38b₁ Side surface
38b₂ Bottom surface
39 Alumina material
40 Support substrate
100 Electronic device
101 Solid-state imaging apparatus
102 Optical lens
103 Shutter device
104 Drive circuit
105 Signal processing circuit
106 Incident light
a Arrow
da First thickness
db Second thickness
dc1, dc2 Third thickness
de Fourth thickness
df Fifth thickness
RM Mask
wa, wb, wAa, wAb Width

What is claimed is:

1. A solid-state imaging apparatus comprising:
a first charge accumulation region and a second charge accumulation region provided separated from each other in a semiconductor layer; and
a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel, wherein
the gate insulating film has a thickness that is thinner on a downstream side in a transfer direction of the signal charges than on an upstream side in the transfer direction of the signal charges.

2. The solid-state imaging apparatus according to claim 1, wherein
the gate insulating film includes a first portion provided on the upstream side in the transfer direction of the signal charges and having a first thickness, and a second portion provided on the downstream side in the transfer direction of the signal charges and having a second thickness thinner than the first thickness.

3. The solid-state imaging apparatus according to claim 1, wherein
the gate insulating film includes a first portion provided on the upstream side in the transfer direction of the signal charges and having a first thickness, and a second portion provided on the downstream side in the transfer direction of the signal charges and having a second thickness thinner than the first thickness, and
the first portion has a width in the transfer direction of the signal charges, the width being equal to a width of the second portion in the transfer direction of the signal charges.

4. The solid-state imaging apparatus according to claim 1, wherein
the gate insulating film includes a first portion provided on the upstream side in the transfer direction of the signal charges and having a first thickness, and a second portion provided on the downstream side in the transfer direction of the signal charges and having a second thickness thinner than the first thickness, and
the first portion has a width in the transfer direction of the signal charges, the width being different from a width of the second portion in the transfer direction of the signal charges.

5. The solid-state imaging apparatus according to claim 1, wherein
the gate insulating film includes a first portion provided on the upstream side in the transfer direction of the signal charges and having a first thickness, a second portion provided on the downstream side in the transfer direction of the signal charges and having a second thickness thinner than the first thickness, and a third portion provided between the first portion and the second portion and having a third thickness thinner than the first thickness and thicker than the second thickness.

6. The solid-state imaging apparatus according to claim 1, wherein
the gate insulating film becomes gradually thinner from the upstream side in the transfer direction of the signal charges toward the downstream side in the transfer direction of the signal charges.

7. The solid-state imaging apparatus according to claim 1, wherein
the first charge accumulation region and the second charge accumulation region are disposed side by side on a side of a first surface of the semiconductor layer in a direction orthogonal to a thickness direction of the semiconductor layer,
the gate electrode includes a head part provided on the side of the first surface of the semiconductor layer with the gate insulating film interposed between the head part and the semiconductor layer, and a body part protruding from the head part to an inside of the semiconductor layer with the gate insulating film interposed between the body part and the semiconductor layer, between the first charge accumulation region and the second charge accumulation region, and
the gate insulating film has a thickness between the body part and the semiconductor layer, the thickness being thinner on the downstream side in the transfer direction of the signal charges than on the upstream side in the transfer direction of the signal charges.

8. The solid-state imaging apparatus according to claim 7, wherein
the gate insulating film includes a fourth portion and a fifth portion provided between a side surface of the body part and the semiconductor layer,
the fourth portion is provided on a side of the first charge accumulation region, and the fifth portion is provided on a side of the second charge accumulation region, and
the fifth portion has a fifth thickness thinner than a fourth thickness that is a thickness of the fourth portion.

9. The solid-state imaging apparatus according to claim 1, wherein
the second charge accumulation region is disposed on a side of a first surface of the semiconductor layer,
the first charge accumulation region is disposed on a position deeper than the second charge accumulation region from the first surface of the semiconductor layer,
the gate electrode includes a head part provided on the side of the first surface of the semiconductor layer with the gate insulating film interposed between the head part and the semiconductor layer, and a body part protruding from the head part to an inside of the semiconductor layer with the gate insulating film interposed between the body part and the semiconductor layer, in a region where the gate electrode overlaps the first charge accumulation region in plan view, and
the gate insulating film has a thickness between the body part and the semiconductor layer, the thickness being thinner on the downstream side in the transfer direction of the signal charges than on the upstream side in the transfer direction of the signal charges.

10. The solid-state imaging apparatus according to claim 9, wherein
the gate insulating film includes a seventh portion provided between a side surface of the body part and the semiconductor layer, and a sixth portion provided between a bottom surface of the body part and the semiconductor layer, and
the sixth portion has a fifth thickness thinner than a fourth thickness that is a thickness of the seventh portion.

11. A solid-state imaging apparatus comprising:
a first charge accumulation region and a second charge accumulation region provided separated from each other in a semiconductor layer; and
a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel, wherein
the gate insulating film includes an eighth portion having a first relative dielectric constant and a ninth portion having a second relative dielectric constant higher than the first relative dielectric constant, and
the ninth portion is provided on a downstream side in a transfer direction of the signal charges in the gate insulating film.

12. The solid-state imaging apparatus according to claim 11, wherein
the eighth portion includes a silicon oxide film, and the ninth portion includes a silicon oxynitride film.

13. The solid-state imaging apparatus according to claim 11, wherein
the eighth portion includes a silicon oxide film, and the ninth portion includes a high dielectric constant gate insulating film.

14. A method of manufacturing a solid-state imaging apparatus, the method comprising:
forming a first charge accumulation region and a second charge accumulation region in a semiconductor layer;
forming a transfer transistor having a gate electrode and a gate insulating film and configured to transfer signal charges accumulated in the first charge accumulation region to the second charge accumulation region; and
forming the gate insulating film having a thickness that is thinner on a downstream side in a transfer direction of the signal charges than a thickness of the gate insulating film on an upstream side in the transfer direction of the signal charges.

15. A method of manufacturing a solid-state imaging apparatus, the method comprising:
forming a first charge accumulation region and a second charge accumulation region in a semiconductor layer;
forming a transfer transistor having a gate electrode and a gate insulating film and configured to transfer signal charges accumulated in the first charge accumulation region to the second charge accumulation region; and
forming the gate insulating film having a larger relative dielectric constant on a downstream side in a transfer direction of the signal charges than a relative dielectric constant of the gate insulating film on an upstream side in the transfer direction of the signal charges.

16. An electronic device comprising:
a solid-state imaging apparatus;
an optical lens that forms an image of image light from a subject on an imaging surface of the solid-state imaging apparatus; and
a signal processing circuit that performs signal processing on a signal output from the solid-state imaging apparatus, wherein
the solid-state imaging apparatus includes:
a first charge accumulation region and a second charge accumulation region provided separated from each other in a semiconductor layer; and
a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel, and
the gate insulating film of the solid-state imaging apparatus has a thickness that is thinner on a downstream side in a transfer direction of the signal charges than on an upstream side in the transfer direction of the signal charges.

17. An electronic device comprising:
a solid-state imaging apparatus;
an optical lens that forms an image of image light from a subject on an imaging surface of the solid-state imaging apparatus; and
a signal processing circuit that performs signal processing on a signal output from the solid-state imaging apparatus, wherein
the solid-state imaging apparatus includes:
a first charge accumulation region and a second charge accumulation region provided separated from each other in a semiconductor layer; and
a transfer transistor in which a channel is formed in the semiconductor layer adjacent to a gate electrode with a gate insulating film interposed between the semiconductor layer and the gate electrode, and signal charges accumulated in the first charge accumulation region are transferred to the second charge accumulation region through the channel,
the gate insulating film includes an eighth portion having a first relative dielectric constant and a ninth portion having a second relative dielectric constant higher than the first relative dielectric constant, and
the ninth portion is provided on a downstream side in a transfer direction of the signal charges in the gate insulating film.
